(19) United States
(12) Patent Application Publication
(10) Pub. No.: US 2020/0381269 A1
(43) Pub. Date: Dec. 3, 2020

(54) SUBSTRATE PROCESSING METHOD AND SUBSTRATE PROCESSING APPARATUS

(71) Applicant: SCREEN Holdings Co., Ltd., Kyoto (JP)

(72) Inventors: Naozumi FUJIWARA, Kyoto (JP); Masayuki OTSUJI, Kyoto (JP); Masahiko KATO, Kyoto (JP); Yu YAMAGUCHI, Kyoto (JP)

(21) Appl. No.: 16/885,703

(22) Filed: May 28, 2020

(30) Foreign Application Priority Data
May 30, 2019 (JP) 2019-101599

(51) Int. Cl. H01L 21/67; H01L 21/687; H01L 21/04; H01L 21/02

(52) U.S. Cl. CPC H01L 21/67051; H01L 21/02068; H01L 21/0445; H01L 21/68714

(57) ABSTRACT

A substrate processing method includes a sublimable-substance-containing liquid film forming step of supplying a sublimable-substance-containing liquid to a surface of a substrate on which a pattern is formed, so that a liquid film of the sublimable-substance-containing liquid covering the surface of the substrate is formed on the surface of the substrate, a transition state film forming step of evaporating the solvent from the liquid film to form solids of the sublimable substance, so that a transition state film, that is in a pre-crystal transition state before the solids of the sublimable substance crystallize, is formed on the surface of the substrate, and a transition state film removing step of sublimating the solids of the sublimable substance on the surface of the substrate while maintaining the solids of the sublimable substance in the pre-crystal transition state, so that the transition state film from the surface of the substrate is removed.

### CROSS REFERENCE TO RELATED APPLICATIONS

This application claims the benefit of priority to Japanese Patent Application No. 2019-101599 filed on May 30, 2019. The entire contents of this application are hereby incorporated herein by reference.

### BACKGROUND OF THE INVENTION

### 1. Field of the Invention

The present invention relates to a substrate processing method and a substrate processing apparatus for processing substrates. Examples of substrates to be processed include substrates such as semiconductor wafers, substrates for liquid crystal display devices, substrates for FPDs (flat panel displays), such as organic EL (electroluminescence) display devices, etc., substrates for optical disks, substrates for magnetic disks, substrates for magneto-optical disks, substrates for photomasks, ceramic substrates, substrates for solar cells, etc.

### 2. Description of the Related Art

In a manufacturing process of semiconductor devices and liquid crystal display devices, etc., processing is performed as necessary on a substrate. Such processing includes supplying a chemical liquid and a rinse liquid, etc., to the substrate. After the rinse liquid is supplied, the rinse liquid is removed from the substrate and the substrate is dried. With a single substrate processing type substrate processing apparatus that processes substrates one at a time, spin drying with which the substrate is dried by removing the liquid attached to the substrate by high speed rotation of the substrate is performed.

If a pattern is formed on a surface of the substrate, surface tension of the rinse liquid attached to the substrate acts on the pattern when the substrate is being dried and, at times, the pattern collapses. As a countermeasure against this, a method such as supplying IPA (isopropyl alcohol) or other liquid of low surface tension to the substrate or a method such as supplying a hydrophobizing agent to the substrate to hydrophobize the surface of the substrate and thereby reduce the surface tension applied to the pattern by the liquid is adopted. However, even if IPA or a hydrophobizing agent is used to reduce the surface tension acting on the pattern, depending on the pattern strength, it may not be possible to prevent pattern collapse sufficiently.

Recently, sublimation drying is being noted as a technique for drying a substrate while preventing pattern collapse. An example of a substrate processing method and a substrate processing apparatus with which sublimation drying is performed is disclosed in Japanese Patent Application Publication No. 2018-139331. With the sublimation drying described in Japanese Patent Application Publication No. 2018-139331, a solution of a sublimable substance is supplied to a surface of a substrate and DIW (deionized water) on the substrate is replaced by the solution of the sublimable substance. Thereafter, by evaporating a solvent in the solution of the sublimable substance, the sublimable substance is precipitated and a film constituted of the sublimable substance in a solid state is formed. The substrate is then heated to sublimate the sublimable substance to thereby remove the film constituted of the sublimable substance from the substrate.

### SUMMARY OF THE INVENTION

With the sublimation drying disclosed in Japanese Patent Application Publication No. 2018-139331, the sublimable substance in the solid state is sublimated after evaporating the solvent from the substrate to form the film constituted of the sublimable substance in the solid state and eliminating liquid from the substrate. Therefore, surface tension acting on the pattern from the liquid can be reduced.

However, it is possible for a force from solids of the sublimable substance to act on the pattern on the substrate. In detail, the solids of the sublimable substance formed in sublimation drying may crystallize at times as shown in FIG. 14. Inside a crystal Cr of the sublimable substance, molecules of the sublimable substance are arranged regularly. An alignment (orientation) of a crystal Cr differs according to each crystal Cr. Therefore, an interface (crystal interface CI) that accompanies stress (shear stress) is formed mutually between adjacent crystals Cr. A force may act on a pattern in a vicinity of a crystal interface CI of the sublimable substance due to stress generated in the crystal interface CI of the sublimable substance.

Thus, an object of the present invention is to provide a substrate processing method and a substrate processing apparatus by which collapse of a pattern on a substrate can be lessened by reducing influence of stress due to crystallization of solids of a sublimable substance.

A preferred embodiment of the present invention provides a substrate processing method including a sublimable-substance-containing liquid film forming step of supplying a sublimable-substance-containing liquid being a solution containing a sublimable substance changing from a solid to a gas without passing through a liquid state and a solvent dissolving the sublimable substance to a surface of a substrate on which a pattern is formed to form, on the surface of the substrate, a liquid film of the sublimable-substance-containing liquid covering the surface of the substrate, a transition state film forming step of evaporating the solvent from the liquid film to form solids of the sublimable substance to form, so that a transition state film that is in a pre-crystal transition state before the solids of the sublimable substance crystallize, is formed on the front surface of the substrate, and a transition state film removing step of sublimating the solids of the sublimable substance on the surface of the substrate while maintaining the solids of the sublimable substance in the pre-crystal transition state to remove the transition state film from the surface of the substrate.

According to the present method, the transition state film is formed on the surface of the substrate by evaporating the solvent from the liquid film of the sublimable-substance-containing liquid. The solids of the sublimable substance inside the transition state film are in a pre-crystal transition state before crystallization. Thereafter, the transition state film is removed from the surface of the substrate by the solids of the sublimable substance inside the transition state film being sublimated while being maintained in the pre-crystal transition state. That is, the transition state film is removed from the surface of the substrate without passing through a state in which the solids of the sublimable substance are crystallized. Collapse of a pattern on the substrate can thus be lessened by reducing the influence of stress due to the crystallization of the solids of the sublimable substance.

In the present Description, that the solids of the sublimable substance crystallize does not simply mean that crystals of the sublimable substance are formed. That the solids of the sublimable substance crystallize means that the crystals of the sublimable substance grow to a degree where adjacent crystals mutually form a crystal interface that accompanies stress. Specifically, it means that the crystals of the sublimable substance grow to a size not less than a mutual interval between patterns.

In the preferred embodiment of the present invention, the solids of the sublimable substance inside the transition state film include amorphous solids. The molecules of the sublimable substance inside the amorphous solid are arranged irregularly. Due to being amorphous solids, the solids of the sublimable substance, unlike the solids of the crystallized sublimable substance, do not have a clear interface. Therefore, a physical force exerted by the amorphous solids of the sublimable substance on the pattern on the surface of the substrate is small. The collapse of the pattern can thus be suppressed.

In the preferred embodiment of the present invention, the solids of the sublimable substance inside the transition state film include microcrystalline solids. The microcrystalline solids are solids in which the molecules of the sublimable substance are arranged regularly and are solids of a size such that adjacent solids do not surface-contact each other. Stress is thus unlikely to occur mutually between the microcrystalline solids of the sublimable substance and therefore a physical force is unlikely to be applied to the pattern on the surface of the substrate. The collapse of the pattern can thus be suppressed.

In the preferred embodiment of the present invention, a transition state film forming time that is a time from when the transition state film forming step is started to when the transition state film removing step is started is longer than half of a crystallization time that is a time required until crystals of the sublimable substance form from when the transition state film forming step is started. Further, the transition state film forming time is shorter than the crystallization time.

If the transition state film forming time is too short, an amount of the solvent remaining on the surface of the substrate at a time at which the transition state film removing step is started would be comparatively large. Therefore, when the sublimable substance is sublimated, surface tension of the solvent on the surface of the substrate may act on the pattern and the pattern may collapse. Oppositely, if the transition state film forming time is too long, the solids of the sublimable substance would be sublimated in the crystallized state. The pattern may thus collapse due to a force that acts on the pattern due to the stress generated at the crystal interface.

Thus, if the transition state film forming time is longer than half the crystallization time and shorter than the crystallization time, the crystallization of the solids of the sublimable substance can be avoided while sufficiently reducing the amount of the solvent remaining on the surface of the substrate at the start of the transition state film removing step. The collapse of the pattern on the substrate can thereby be lessened. Especially, if the transition state film forming time is a time of a length of ⅔rd the crystallization time, the collapse of the pattern on the substrate can be lessened further.

In the preferred embodiment of the present invention, the substrate processing method further includes a film thinning step of rotating the substrate around a vertical axis passing through a central part of the surface of the substrate to eliminate the sublimable-substance-containing liquid from the surface of the substrate to thin the liquid film before execution of the transition state film forming step. Thus, in the transition state film forming step executed after the film thinning step, the transition state film can be formed by evaporating the solvent from the thinned liquid film of the sublimable-substance-containing liquid. The transition state film can thus be formed quickly.

In the preferred embodiment of the present invention, the transition state film forming step includes a step of rotating the substrate around a vertical axis passing through a central part of the surface of the substrate to evaporate the solvent in the liquid film to form the transition state film. The solvent can thus be evaporated quickly from the liquid film of the sublimable-substance-containing liquid. The transition state film can thus be formed quickly.

In the preferred embodiment of the present invention, the substrate processing method further includes a film thinning step of rotating the substrate at a predetermined first rotational speed around a vertical axis passing through a central part of the surface of the substrate to make a centrifugal force act on the liquid film on the surface of the substrate to thin the liquid film. Also, the transition state film forming step includes a step of changing the rotational speed of the substrate to a predetermined second rotational speed lower than the first rotational speed to evaporate the solvent in the liquid film to form the transition state film after the film thinning step.

According to the present method, in the film thinning step, the substrate is rotated at the first rotational speed that is a comparatively high speed. The sublimable-substance-containing liquid is thus eliminated quickly from the surface of the substrate by the centrifugal force. Also, the liquid film of the sublimable-substance-containing liquid on the surface of the substrate can be thinned quickly. Then, in the transition state film forming step, the substrate is rotated at the second rotational speed that is a comparatively low speed. The centrifugal force acting on the liquid film of the sublimable-substance-containing liquid on the surface of the substrate can thereby be reduced. The solvent can thus be evaporated from the liquid film to form the transition state film quickly while preventing the sublimable-substance-containing liquid from being eliminated completely from the surface of the substrate, that is, while maintaining the liquid film of the sublimable-substance-containing liquid on the substrate.

In the preferred embodiment of the present invention, the transition state film removing step includes a blowing-on sublimating step of blowing a gas onto the transition state film to sublimate the solids of the sublimable substance on the surface of the substrate.

According to the present method, the solids of the sublimable substance on the surface of the substrate can be sublimated by a simple method of blowing-on of the gas.

In the preferred embodiment of the present invention, the blowing-on sublimating step includes a dry region forming step of blowing the gas onto a central region of the surface of the substrate to sublimate the solids of the sublimable substance, so that a dry region is formed at the central region of the surface of the substrate, and a dry region enlarging step of enlarging the dry region while moving a blowing-on position of the gas at the surface of the substrate toward a peripheral edge region of the surface of the substrate.

According to the present method, the dry region is formed by blowing the gas onto the central region of the surface of the substrate. Thereafter, the blowing-on position of the gas is moved toward the peripheral edge region of the surface of the substrate. A blowing-on force of the gas can thus be made to act efficiently on the solids of the sublimable substance in a vicinity of a peripheral edge of the dry region. The dry region can thus be enlarged quickly. Consequently, a difference in time from when formation of the transition state film is started to when the solids of the sublimable substance sublimate between the central region of the surface of the substrate and the peripheral edge region of the surface of the substrate can be reduced. The collapse of the pattern can thus be lessened across an entirety of the surface of the substrate.

Another preferred embodiment of the present invention provides a substrate processing apparatus including a sublimable-substance-containing liquid supplying unit that supplies a sublimable-substance-containing liquid being a solution containing a sublimable substance changing from a solid to a gas without passing through a liquid state and a solvent dissolving the sublimable substance to a surface of a substrate, a substrate rotating unit that rotates the substrate around a vertical axis passing through a central part of the surface of the substrate, a sublimating unit that sublimates solids of the sublimable substance from the surface of the substrate, and a controller that controls the sublimable-substance-containing liquid supplying unit, the substrate rotating unit, and the sublimating unit.

Also, the controller is programmed to execute a sublimable-substance-containing liquid film forming step of supplying the sublimable-substance-containing liquid from the sublimable-substance-containing liquid supplying unit to the surface of the substrate on which a pattern is formed, so that a liquid film of the sublimable-substance-containing liquid covering the surface of the substrate is formed on the surface of the substrate, a transition state film forming step of evaporating the solvent from the liquid film by the substrate rotating unit to form the solids of the sublimable substance, so that a transition state film, that is in a pre-crystal transition state before the solids of the sublimable substance crystallize, is formed on the surface of the substrate, and a transition state film removing step of sublimating the solids of the sublimable substance on the surface of the substrate by the sublimating unit while maintaining the solids of the sublimable substance in the pre-crystal transition state.

According to the present apparatus, the transition state film is formed on the surface of the substrate by evaporating the solvent from the liquid film of the sublimable-substance-containing liquid. The solids of the sublimable substance inside the transition state film are in a pre-crystal transition state before crystallization. Thereafter, the transition state film is removed from the surface of the substrate by the solids of the sublimable substance inside the transition state film being sublimated while being maintained in the pre-crystal transition state. That is, the transition state film is removed from the surface of the substrate without passing through a state in which the solids of the sublimable substance are crystallized. Collapse of a pattern on the substrate can thus be lessened by reducing the influence of stress due to the crystallization of the solids of the sublimable substance.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of a layout of a substrate processing apparatus according to a first preferred embodiment of the present invention.

FIG. 2 is a schematic partial sectional view of the general configuration of a processing unit included in the substrate processing apparatus.

FIG. 3 is a block diagram of the electrical configuration of a main portion of the substrate processing apparatus.

FIG. 4 is a flowchart for describing an example of substrate processing by the substrate processing apparatus.

FIG. 5A is a schematic view for describing conditions of a sublimable-substance-containing liquid film forming step (step S5) in the substrate processing.

FIG. 5B is a schematic view for describing conditions of a film thinning step (step S6) in the substrate processing.

FIG. 5C is a schematic view for describing conditions of a transition state film forming step (step S7) in the substrate processing.

FIG. 5D is a schematic view for describing conditions of the transition state film forming step (step S7).

FIG. 5E is a schematic view for describing conditions of a transition state film removing step (step S8) in the substrate processing.

FIG. 5F is a schematic view for describing conditions of the transition state film removing step (step S8).

FIG. 5G is a schematic view for describing conditions of a lower surface rinsing step (step S9) in the substrate processing.

FIG. 6A is a schematic view for describing an example of conditions of a surface of a substrate in the transition state film forming step (step S7).

FIG. 6B is a schematic view for describing the example of conditions of the surface of the substrate in the transition state film forming step (step S7).

FIG. 7 is a schematic view for describing another example of conditions of the surface of the substrate in the transition state film forming step (step S7).

FIG. 8A is a schematic view for describing conditions of the transition state film removing step (step S8) by a substrate processing apparatus according to a second preferred embodiment of the present invention.

FIG. 8B is a schematic view for describing conditions of the transition state film removing step (step S8) by the substrate processing apparatus according to the second preferred embodiment.

FIG. 9 is a graph showing results of an experiment using small-piece substrates and is a graph showing a relationship of rotational speed of a small-piece substrate and crystallization time.

FIG. 10 is a graph showing results of an experiment using small-piece substrates and is a graph showing a relationship of transition state film forming time and pattern collapse rate.

FIG. 11A is a graph showing results of an experiment performed to examine a relationship of the transition state film forming time and the pattern collapse rate.

FIG. 11B is a graph showing results of the experiment performed to examine the relationship of the transition state film forming time and the pattern collapse rate.

FIG. 11C is a graph showing results of the experiment performed to examine the relationship of the transition state film forming time and the pattern collapse rate.

FIG. 11D is a graph showing results of the experiment performed to examine the relationship of the transition state film forming time and the pattern collapse rate.

FIG. 12A is a graph showing results of an experiment performed to examine a relationship of rotational speed of a substrate in the film thinning step and the pattern collapse rate.

FIG. 12B is a graph showing results of the experiment performed to examine the relationship of the rotational speed of the substrate in the film thinning step and the pattern collapse rate.

FIG. 12C is a graph showing results of the experiment performed to examine the relationship of the rotational speed of the substrate in the film thinning step and the pattern collapse rate.

FIG. 13A is a graph showing results of an experiment performed to examine a relationship of rotational speed of the substrate in the transition state film forming step and the pattern collapse rate.

FIG. 13B is a graph showing results of the experiment performed to examine the relationship of the rotational speed of the substrate in the transition state film forming step and the pattern collapse rate.

FIG. 14 is a schematic view for describing conditions of a surface of a substrate when solids of a sublimable substance crystallize.

### DETAILED DESCRIPTION OF THE PREFERRED EMBODIMENTS

### First Preferred Embodiment

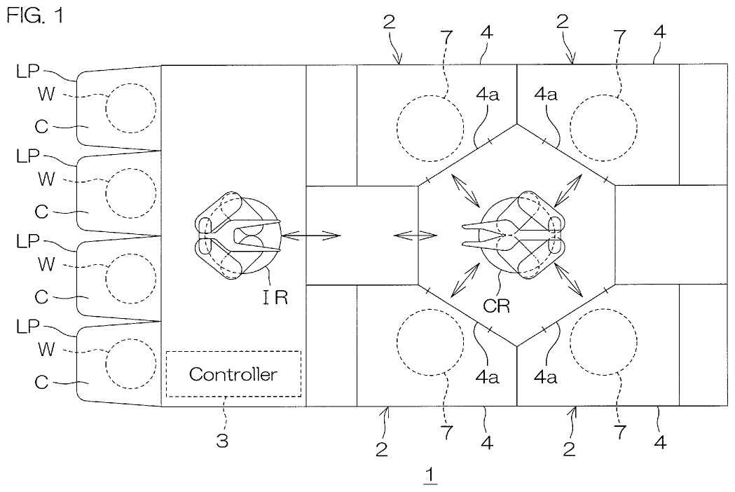

FIG. 1 is a schematic plan view of a layout of a substrate processing apparatus 1 according to a first preferred embodiment of the present invention.

The substrate processing apparatus 1 is a single substrate processing type apparatus that processes a substrate W, such as a silicon wafer, etc., one at a time. In the present preferred embodiment, the substrate W is a disk-shaped substrate.

The substrate processing apparatus 1 includes a plurality of processing units 2 for processing substrates W with fluids, load ports LP on which are placed carriers C that house a plurality of the substrates W to be processed by the processing units 2, transfer robots IR and CR that transfer the substrates W between the load ports LP and the processing units 2, and a controller 3 that controls the substrate processing apparatus 1.

The transfer robot IR transfers the substrates W between the carriers C and the transfer robot CR. The transfer robot CR transfers the substrates W between the transfer robot IR and the processing units 2. The plurality of processing units 2 have, for example, the same configuration. Although the details will be described later, processing liquids supplied to the substrate W inside the processing unit 2 include a chemical liquid, a rinse liquid, a replacing liquid, a sublimable-substance-containing liquid, a heating medium, etc.

Each processing unit 2 includes a chamber 4 and a processing cup 7 disposed inside the chamber 4 and executes processing of the substrate W inside the processing cup 7. An inlet/outlet 4a for carrying in the substrates W and carrying out the substrates W by the transfer robot CR is formed at the chamber 4. The chamber 4 is provided with a shutter unit (not shown) for opening/closing the inlet/outlet 4a.

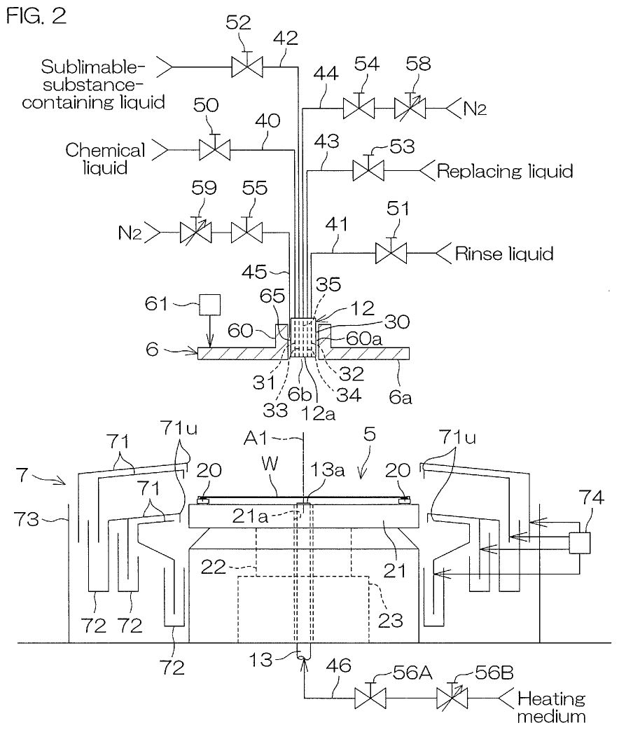

FIG. 2 is a schematic view for describing an configuration example of the processing unit 2. The processing unit 2 includes a spin chuck 5, a facing member 6, a processing cup 7, a central nozzle 12, and a lower surface nozzle 13.

The spin chuck 5 rotates the substrate W around a vertical rotational axis A1 (a vertical axis), passing through a central part of the substrate W, while holding the substrate W horizontally. The spin chuck 5 includes a plurality of chuck pins 20, a spin base 21, a rotating shaft 22, and a spin motor 23.

The spin base 21 has a disk shape oriented along a horizontal direction. On an upper surface of the spin base 21, a plurality of chuck pins 20 that grip a peripheral edge of the substrate W are disposed at intervals in a circumferential direction of the spin base 21. The spin base 21 and the plurality of chuck pins 20 constitute a substrate holding unit that holds the substrate W horizontally. The substrate holding unit is also referred to as a substrate holder.

The rotating shaft 22 extends in a vertical direction along the rotational axis A1. An upper end portion of the rotating shaft 22 is coupled to a lower surface center of the spin base 21. The spin motor 23 applies a rotating force to the rotating shaft 22. The spin base 21 is rotated by the rotating shaft 22 being rotated by the spin motor 23. The substrate W is thereby rotated around the rotational axis A1. The spin motor 23 is an example of a substrate rotating unit that rotates the substrate W around the rotational axis A1.

The facing member 6 faces the substrate W, held by the spin chuck 5, from above. The facing member 6 is formed to a disk shape having substantially the same diameter as or a diameter equal to or larger than that of the substrate W. The facing member 6 has a facing surface 6a that faces an upper surface (surface on the upper side) of the substrate W. The facing surface 6a is disposed substantially along a horizontal plane higher than the spin chuck 5.

A hollow shaft 60 is fixed to the facing member 6 at an opposite side to the facing surface 6a. An opening 6b that penetrates up and down through the facing member 6 and is in communication with an internal space 60a of the hollow shaft 60 is formed at a portion of the facing member 6 overlapping with the rotational axis A1 in plan view.

The facing member 6 blocks an atmosphere inside a space between the facing surface 6a and the upper surface of the substrate W from an atmosphere outside the space. The facing member 6 is thus also referred to as a blocking plate.

The processing unit 2 further includes a facing member elevating/lowering unit 61 that drives elevation and lowering of the facing member 6. The facing member elevating/lowering unit 61 includes, for example, a ball-screw mechanism (not shown) coupled to a supporting member (not shown) that supports the hollow shaft 60 and an electric motor (not shown) that applies a driving force to the ball-screw mechanism. The facing member elevating/lowering unit 61 is also referred to as a facing member lifter (blocking plate lifter).

The facing member elevating/lowering unit 61 is capable of positioning the facing member 6 at any position (height) from a lower position to an upper position. The lower position is a position within a movable range of the facing member 6 at which the facing surface 6a is positioned most proximate to the substrate W. When the facing member 6 is positioned at the lower position, a distance between the upper surface of the substrate W and the facing surface 6a is, for example, 1 mm. The upper position is a position within the movable range of the facing member 6 at which the facing surface 6a is separated farthest from the substrate W.

The processing cup 7 includes a plurality of guards 71 that receive liquid splashed outward from the substrate W held by the spin chuck 5, a plurality of cups 72 that receive liquid guided downward by the plurality of guards 71, and a circular-cylindrical outer wall member 73 that surrounds the plurality of guards 71 and the plurality of cups 72. FIG. 2 shows an example where four guards 71 and three cups 72 are provided and the cup 72 at an outermost side is integral to the third guard 71 from the top.

The processing unit 2 includes a guard elevating/lowering unit 74 that elevates and lowers the plurality of guards 71 individually. The guard elevating/lowering unit 74 includes, for example, a plurality of ball-screw mechanisms (not shown) coupled to the respective guards 71 and a plurality of motors (not shown) that respectively apply driving forces to the respective ball screw mechanisms. The guard elevating/lowering unit 74 is also referred to as a guard lifter.

The guard elevating/lowering unit 74 positions each guard 71 at any position from an upper position to a lower position. FIG. 2 shows a state where two guards 71 are positioned at the upper positions and the remaining two guards 71 are positioned at the lower positions. When a guard 71 is positioned at the upper position, an upper end 71u of the guard 71 is disposed higher than the substrate W held by the spin chuck 5. When the guard 71 is positioned at the lower position, the upper end 71u of the guard 71 is disposed lower than the substrate W held by the spin chuck 5.

When a processing liquid is supplied to the substrate W that is rotating, at least one of the guards 71 is disposed at the upper position. When the processing liquid is supplied to the substrate W in this state, the processing liquid is spun off from the substrate W by a centrifugal force. The processing liquid that has been spun off collides with an inner surface of a guard 71 that faces the substrate W horizontally and is guided to the cup 72 corresponding to this guard 71. The processing liquid expelled from the substrate W is thereby collected in the processing cup 7.

The central nozzle 12 is housed in the internal space 60a of the hollow shaft 60 of the facing member 6. A discharge port 12a provided at a tip of the central nozzle 12 faces a central region of the upper surface of the substrate W from above. The central region of the upper surface of the substrate W is a region of a rotation center (central part) of the upper surface of the substrate W and its periphery. On the other hand, a region of a peripheral edge of the upper surface of the substrate W and the vicinity of the peripheral edge is referred to as a peripheral edge region of the upper surface of the substrate. The central nozzle 12 is elevated and lowered together with the facing member 6.

The central nozzle 12 includes a plurality of tubes (a first tube 31, a second tube 32, a third tube 33, a fourth tube 34, and a fifth tube 35) that each discharge a fluid downward and a cylindrical casing 30 that surrounds the plurality of tubes. The plurality of tubes and the casing 30 extend in an up/down direction along the rotational axis A1. The discharge port 12a of the central nozzle 12 is also a discharge port of the first tube 31, is also a discharge port of the second tube 32, and is also a discharge port of the third tube 33. Further, the discharge port 12a of the central nozzle 12 is also a discharge port of the fourth tube 34 and is also a discharge port of the fifth tube 35.

The first tube 31 (central nozzle 12) is an example of a chemical liquid supplying unit that supplies (discharges) the chemical liquid in a continuous flow to the upper surface of the substrate W. The second tube 32 (central nozzle 12) is an example of a rinse liquid supplying unit that supplies (discharges) the rinse liquid in a continuous flow to the upper surface of the substrate W. The third tube 33 (central nozzle 12) is an example of a sublimable-substance-containing liquid supplying unit that supplies (discharges) the sublimable-substance-containing liquid in a continuous flow to the upper surface of the substrate W. The fourth tube 34 (central nozzle 12) is an example of a replacing liquid supplying unit that supplies (discharges) the replacing liquid in a continuous flow to the upper surface of the substrate W. The fifth tube 35 is an example of a gas supplying unit that supplies (discharges) a gas between the upper surface of the substrate W and the facing surface 6a of the facing member 6.

The first tube 31 is connected to a chemical liquid piping 40 that guides the chemical liquid to the first tube 31. When a chemical liquid valve 50 interposed in the chemical liquid piping 40 is opened, the chemical liquid is discharged in a continuous flow toward the central region of the upper surface of the substrate W from the first tube 31 (central nozzle 12).

The chemical liquid discharged from the first tube 31 is, for example, a liquid that contains at least one of sulfuric acid, acetic acid, nitric acid, hydrochloric acid, hydrofluoric acid, ammonia water, hydrogen peroxide water, an organic acid (for example, citric acid, oxalic acid, etc.), an organic alkali (for example, TMAH: tetramethylammonium hydroxide, etc.), a surfactant, and a corrosion inhibitor. As examples of chemical liquids in which the above are mixed, SPM solution (sulfuric acid/hydrogen peroxide mixture), SC1 solution (ammonia-hydrogen peroxide mixture), etc., can be cited.

The second tube 32 is connected to a rinse liquid piping 41 that guides the rinse liquid to the second tube 32. When a rinse liquid valve 51 interposed in the rinse liquid piping 41 is opened, the rinse liquid is discharged in a continuous flow toward the central region of the upper surface of the substrate W from the second tube 32 (central nozzle 12).

The rinse liquid discharged from the second tube 32 is, for example, DIW. Besides DIW, a liquid that contains water can be used as the rinse liquid. Besides DIW, for example, carbonated water, electrolyzed ion water, hydrogen water, ozone water, ammonia water, aqueous hydrochloric acid solution of dilute concentration (of, for example, approximately 10 ppm to 100 ppm), etc., can be used as the rinse liquid.

The third tube 33 is connected to a sublimable-substance-containing liquid piping 42 that guides the sublimable-substance-containing liquid to the third tube 33. When a sublimable-substance-containing liquid valve 52 interposed in the sublimable-substance-containing liquid piping 42 is opened, the sublimable-substance-containing liquid is discharged in a continuous flow toward the central region of the upper surface of the substrate W from the third tube 33 (central nozzle 12).

The sublimable-substance-containing liquid discharged from the third tube 33 is a solution that contains a sublimable substance that corresponds to a solute and a solvent that is miscible with the sublimable substance (that dissolves the sublimable substance). Solids of the sublimable substance are precipitated by evaporation (volatilization) of the solvent from the sublimable-substance-containing liquid.

The sublimable substance contained in the sublimable-substance-containing liquid may be a substance that changes from a solid state to a gaseous state without passing through a liquid state at normal temperature (meaning the same as room temperature) or normal pressure (pressure inside the substrate processing apparatus 1; for example, 1 atmosphere or a value close thereto).

The sublimable substance contained in the sublimable-substance-containing liquid has at least one of an amino group, a hydroxyl group, or a carbonyl group. However, the sublimable substance has a maximum of one hydroxyl group per molecule. The sublimable substance preferably contains a hydrocarbon ring or a heterocyclic ring that is a five-membered ring or a six-membered ring.

In the sublimable substance, the amino group and/or the carbonyl group is a portion of the ring of the hydrocarbon ring or the heterocyclic ring. In the sublimable substance, the hydroxyl group is directly added to the ring of the hydrocarbon ring or the heterocyclic ring. That is, with the present embodiment, a compound having a carboxyl group does not correspond to the sublimable substance. Suitably, the sublimable substance has a mother skeleton with a cage type three-dimensional structure. As an example of a cage type three-dimensional structure, 1,4-diazabicyclo[2.2.2]octane (hereinafter, DABCO) can be cited. An advantage is that bulkiness can be suppressed relative to molecular weight. As another mode, a mode where the amino group is directly added to the ring in the sublimable substance is also suitable. For example, 1-adamantanamine has a mother skeleton with a cage type three-dimensional structure and the amino group is not a portion of a ring but is directly added to a ring.

The sublimable substance preferably has 1 to 5 (more suitably 1 to 4 and even more suitably 2 to 4) amino groups, 1 to 3 (more suitably 1 to 2) carbonyl groups, and/or one hydroxyl group per molecule. The amino group includes a mode where bonds of a nitrogen atom are used in a double bond, such as in C═N— (imino group). The number of amino groups is counted by the number of nitrogen atoms present in one molecule. The sublimable substance is preferably of an embodiment having any one type of an amino group, a carbonyl group, or a hydroxyl group in one molecule. The sublimable substance may have a carbonyl group and an amino group in one molecule.

A molecular weight of the sublimable substance is 80 to 300 (preferably, 90 to 200). Although not constrained in theory, if the molecular weight is too large, energy would be required for vaporization and this is considered unsuitable for the method according to the present invention.

The following can be cited as specific examples of the sublimable substance. That is, the sublimable substance is, for example, any of phthalic anhydride, caffeine, melamine, 1,4-benzoquinone, camphor, hexamethylenetetramine, hexahydro-1,3,5-trimethyl-1,3,5-triazine, 1-adamantanol, 1,4-diazabicyclo[2.2.2]octane, borneol, (−)-borneol, (±)-isoborneol, 1,2-cyclohexanedione, 1,3-cyclohexanedione, 1,4-cyclohexanedione, 3-methyl-1,2-cyclopentanedione, (±)-camphor quinone, (−)-camphor quinone, (+)-camphor quinone, and 1-adamantanamine. A mixture of the specific examples given above may be used as the sublimable substance.

A minute amount of impurity may be mixed in the sublimable substance. For example, if the sublimable substance is phthalic anhydride, not more than 2 mass % (suitably not more than 1 mass %, more suitably not more than 0.1 mass %, and even more suitably not more than 0.01 mass %) of an impurity (besides phthalic anhydride) is allowed to be present with respect to a total amount of the sublimable substance.

As the solvent contained in the sublimable-substance-containing liquid, an alcohol, such as methanol (MeOH), ethanol (EtOH), isopropanol (IPA), etc., an alkane, such as hexane, heptane, octane, etc., an ether, such as ethyl butyl ether, dibutyl ether, tetrahydrofuran (THF), etc., a lactic acid ester, such as methyl lactate, ethyl lactate (EL), etc., an aromatic hydrocarbon, such as benzene, toluene, xylene, etc., a ketone, such as acetone, methyl ethyl ketone, methyl isobutyl ketone, 2-heptanone, cyclopentanone, cyclohexanone, etc., an amide, such as N,N-dimethylacetamide, N-methylpyrrolidone, etc., a lactone, such as γ-butyrolactone, etc., and so forth can be cited.

As the ether, besides the above, an ethylene glycol monoalkyl ether, such as ethylene glycol monomethyl ether, ethylene glycol monoethyl ether, etc., an ethylene glycol monoalkyl ether acetate, such as ethylene glycol monomethyl ether acetate, ethylene glycol monoethyl ether acetate, etc., a propylene glycol monoalkyl ether, such as propylene glycol monomethyl ether (PGME), propylene glycol monoethyl ether (PGEE), etc., a propylene glycol monoalkyl ether acetate, such as propylene glycol monomethyl ether acetate (PGMEA), propylene glycol monoethyl ether acetate, etc., and so forth can be cited. As the solvent contained in the sublimable-substance-containing liquid, the above organic solvents can be used alone or two or more types of the organic solvents can be mixed and used.

The solvent contained in the sublimable-substance-containing liquid is preferably selected from MeOH, EtOH, IPA, THF, PGEE, benzene, acetone, methyl isobutyl ketone, cyclopentanone, cyclohexanone, and any combination thereof. The solvent contained in the sublimable-substance-containing liquid is more preferably selected from MeOH, EtOH, IPA, PGEE, acetone, and any combination thereof and even more preferably selected from MeOH, EtOH, IPA, and PGEE. If the solvent contained in the sublimable-substance-containing liquid is a mixed liquid of two types of substances, a volume ratio thereof is preferably 20:80 to 80:20, more preferably 30:70 to 70:30, and even more preferably 40:60 to 60:40.

The fourth tube 34 is connected to a replacing liquid piping 43 that guides the replacing liquid to the fourth tube 34. When a replacing liquid valve 53 interposed in the replacing liquid piping 43 is opened, the replacing liquid is discharged in a continuous flow toward the central region of the upper surface of the substrate W from the fourth tube 34 (central nozzle 12).

The replacing liquid discharged from the fourth tube 34 is, for example, IPA. The replacing liquid may be a mixed liquid of IPA and HFE or may contain at least either of IPA and HFE and a component besides these. IPA is a liquid that is miscible with both water and fluorohydrocarbons.

As shall be described below, the replacing liquid discharged from the fourth tube 34 is supplied to the upper surface of the substrate W that is covered with a liquid film of the rinse liquid and the sublimable-substance-containing liquid discharged from the third tube 33 is supplied to the upper surface of the substrate W that is covered with a liquid film of the replacing liquid. The replacing liquid suffices to be a liquid that is miscible with both the rinse liquid and the sublimable-substance-containing liquid. That is, the replacing liquid suffices to have compatibility (miscibility) with both the rinse liquid and the sublimable-substance-containing liquid. Compatibility is a property of two types of liquids dissolving and mixing mutually.

The fifth tube 35 is connected to a first gas piping 44 that guides a gas to the fifth tube 35. A first gas valve 54 and a first gas flow control valve 58 are interposed in the first gas piping 44. When the first gas valve 54 is opened, the gas is discharged toward the central region from the fifth tube 35 (central nozzle 12). A flow rate of the gas discharged from the discharge port 12a of the central nozzle 12 is adjusted by adjusting an opening degree of the first gas flow control valve 58.

The gas discharged from the central nozzle 12 is an inert gas, for example, nitrogen gas (N₂), etc. The gas discharged from the central nozzle 12 may be air. The inert gas is not restricted to nitrogen gas and is a gas that is inert with respect to the upper surface of the substrate W and a pattern formed on the upper surface of the substrate W. As examples of the inert gas besides nitrogen gas, noble gases, such as argon, etc., can be cited.

An inner peripheral surface of the hollow shaft 60 of the facing member 6 and an outer peripheral surface of the central nozzle 12 define a cylindrical gas flow passage 65 that extends up and down. The gas flow passage 65 is connected to a second gas piping 45 that guides a gas, such as an inert gas, etc., to the gas flow passage 65. A second gas valve 55 and a second gas flow control valve 59 are interposed in the second gas piping 45. When the second gas valve 55 is opened, the gas is discharged downward from a lower end portion of the gas flow passage 65. A flow rate of the gas discharged from the gas flow passage 65 is adjusted by adjusting an opening degree of the second gas flow control valve 59.

The gas discharged from the gas flow passage 65 is the same gas as the gas discharged from the central nozzle 12. That is, the gas discharged from the gas flow passage 65 may be an inert gas, for example, nitrogen gas (N₂), etc., or may be air.

The gas discharged from the gas flow passage 65 and the gas discharged from the central nozzle 12 are both blown onto the central region of the upper surface of the substrate W via the opening 6b of the facing member 6.

The lower surface nozzle 13 is inserted into a penetrating hole 21a that is opened at an upper surface central part of the spin base 21. A discharge port 13a of the lower surface nozzle 13 is exposed from an upper surface of the spin base 21. The discharge port 13a of the lower surface nozzle 13 faces a central part of a lower surface of the substrate W from below.

The lower surface nozzle 13 is connected to a heating medium piping 46 that guides the heating medium to the lower surface nozzle 13. A heating medium valve 56A and a heating medium flow control valve 56B are interposed in the heating medium piping 46. When the heating medium valve 56A is opened, the heating medium is discharged continuously toward a central region of the lower surface of the substrate W from the lower surface nozzle 13. A flow rate of the heating medium discharged from the lower surface nozzle 13 is adjusted by adjusting an opening degree of the heating medium flow control valve 56B. The lower surface nozzle 13 is an example of a heating medium supplying unit that supplies the heating medium for heating the substrate W to the substrate W.

The heating medium discharged from the lower surface nozzle 13 is, for example, high temperature DIW that has a temperature higher than room temperature and lower than a boiling point of the solvent contained in the sublimable-substance-containing liquid. If the solvent contained in the sublimable-substance-containing liquid is, for example, IPA, the temperature of the high temperature DIW is set to 60° C. to 80° C.

The lower surface of the substrate W can also be cleaned by the heating medium discharged from the lower surface nozzle 13. That is, the lower surface nozzle 13 also functions as a lower surface rinse liquid supplying unit that supplies the high temperature DIW as a rinse liquid to the lower surface of the substrate W.

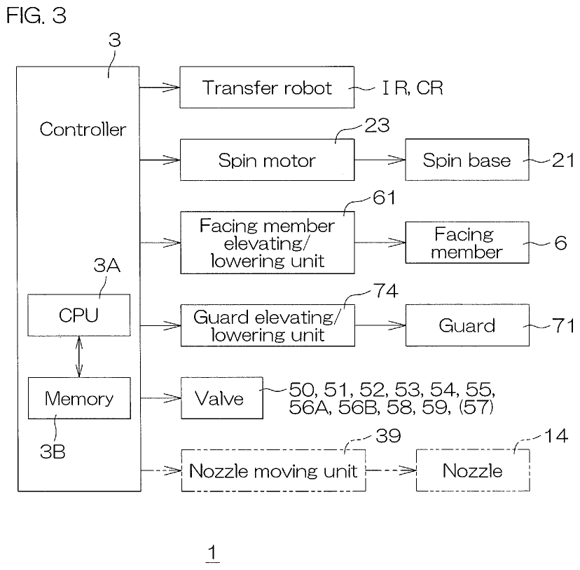

FIG. 3 is a block diagram of the electrical configuration of a main portion of the substrate processing apparatus 1. The controller 3 includes a microcomputer and controls control objects included in the substrate processing apparatus 1 in accordance with a predetermined control program.

Specifically, the controller 3 includes a processor (CPU) 3A and a memory 3B that stores the control program. The controller 3 is configured such that various types of control for substrate processing are executed by the processor 3A executing the control program.

The controller 3 is programmed to control, in particular, the transfer robots IR and CR, the spin motor 23, the facing member elevating/lowering unit 61, the guard elevating/lowering unit 74, the chemical liquid valve 50, the rinse liquid valve 51, the sublimable-substance-containing liquid valve 52, the replacing liquid valve 53, the first gas valve 54, the second gas valve 55, the heating medium valve 56A, the heating medium flow control valve 56B, the first gas flow control valve 58, and the second gas flow control valve 59.

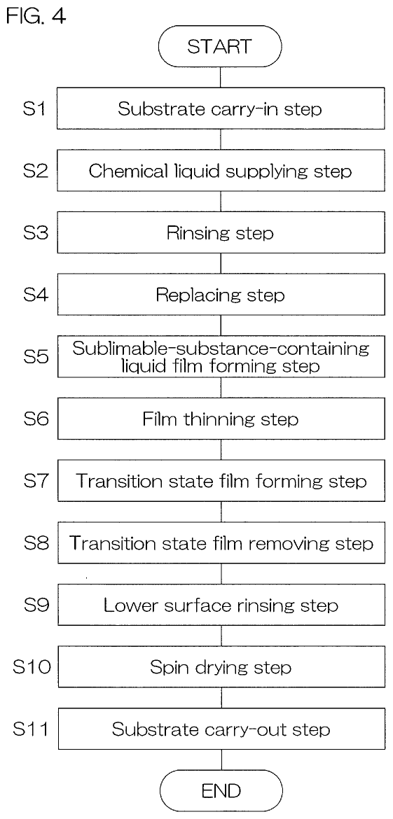

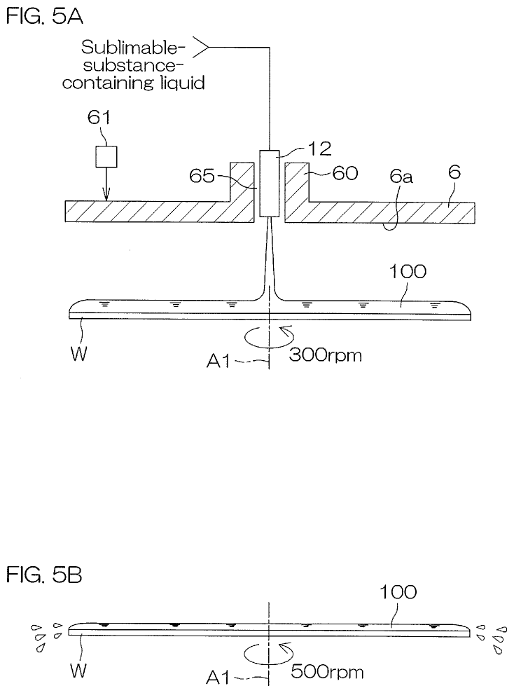

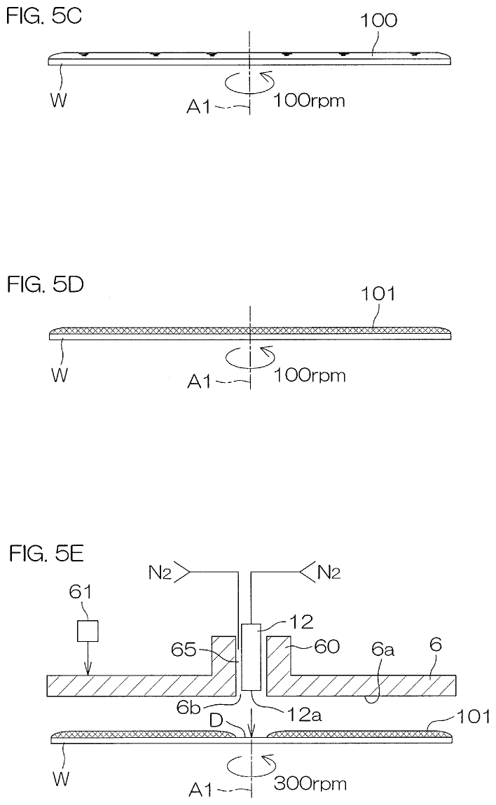

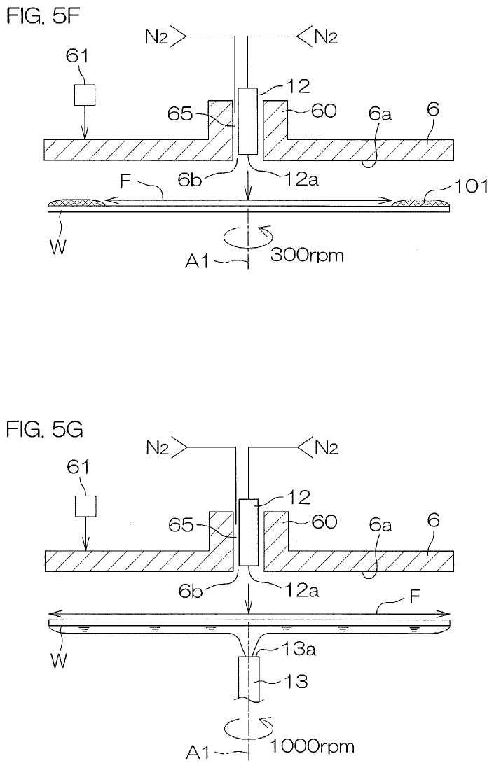

FIG. 4 is a flowchart for describing an example of substrate processing by the substrate processing apparatus 1. FIG. 4 mainly shows processing realized by execution of a program by the controller 3. FIG. 5A to FIG. 5G are schematic views for describing conditions of respective steps of the substrate processing.

In the following, FIG. 2 and FIG. 4 shall mainly be referenced. FIG. 5A to FIG. 5G shall be referenced as appropriate.

In the substrate processing by the substrate processing apparatus 1, for example, as shown in FIG. 4, a substrate carry-in step (step S1), a chemical liquid supplying step (step S2), a rinsing step (step S3), a replacing step (step S4), a sublimable-substance-containing liquid film forming step (step S5), a film thinning step (step S6), a transition state film forming step (step S7), a transition state film removing step (step S8), a lower surface rinsing step (step S9), a spin drying step (step S10), and a substrate carry-out step (step S11) are executed in that order.

First, an unprocessed substrate W is carried from a carrier C into a processing unit 2 by the transfer robots IR and CR (see FIG. 1) and transferred to the spin chuck 5 (step S1). The substrate W is thereby held horizontally by the spin chuck 5 (substrate holding step). The holding of the substrate W by the spin chuck 5 is continued until the spin drying step (step S10) ends. When the substrate W is carried in, the facing member 6 is retreated at the upper position and the plurality of guards 71 are retreated at the lower positions.

After the transfer robot CR has retreated outside the processing unit 2, the chemical liquid supplying step (step S2) is started. In the chemical liquid supplying step, the upper surface of the substrate W is processed by the chemical liquid.

Specifically, the spin motor 23 rotates the spin base 21. The horizontally held substrate W is thereby rotated (substrate rotating step). In the chemical liquid supplying step, the substrate W is rotated at a predetermined chemical liquid speed. The chemical liquid speed is, for example, 1200 rpm.

The facing member elevating/lowering unit 61 moves the facing member 6 to a processing position between the upper position and the lower position. Then, in a state where the facing member 6 is positioned at the processing position and at least one of the guards 71 is positioned at the upper position, the chemical liquid valve 50 is opened. The chemical liquid is thereby supplied (discharged) from the central nozzle 12 toward the central region of the upper surface of the substrate W in the rotating state (chemical liquid supplying step, chemical liquid discharging step).

The chemical liquid discharged from the central nozzle 12 lands on the upper surface of the substrate W in the rotating state and thereafter flows outward along the upper surface of the substrate W due to a centrifugal force. The chemical liquid is thus supplied to the entire upper surface of the substrate W and a liquid film of the chemical liquid that covers the entire upper surface of the substrate W is formed.

Next, the rinsing step (step S3) is started. In the rinsing step, the chemical liquid on the substrate W is washed away with the rinse liquid.

Specifically, when a predetermined time elapses from when the discharge of the chemical liquid is started, the chemical liquid valve 50 is closed. The supply of the chemical liquid to the substrate W is thereby stopped. Then, with the facing member 6 being maintained at the processing position, the rinse liquid valve 51 is opened. The rinse liquid is thereby supplied (discharged) from the central nozzle 12 toward the central region of the upper surface of the substrate W in the rotating state (rinse liquid supplying step, rinse liquid discharging step).

Before the discharge of the rinse liquid is started, the guard elevating/lowering unit 74 may move at least one of the guards 71 vertically to switch the guard 71 that receives liquid expelled from the substrate W.

In the rinsing step, the substrate W is rotated at a predetermined rinsing speed. The rinsing speed is, for example, 1200 rpm.

The rinse liquid discharged from the central nozzle 12 lands on the upper surface of the substrate W in the rotating state and thereafter flows outward along the upper surface of the substrate W due to a centrifugal force. The rinse liquid is thus supplied to the entire upper surface of the substrate W and a liquid film of the rinse liquid that covers the entire upper surface of the substrate W is formed.

Next, the replacing step (step S4) of supplying the replacing liquid having compatibility with both the rinse liquid and the sublimable-substance-containing liquid to the upper surface of the substrate W to replace the rinse liquid on the substrate W with the replacing liquid is performed.

Specifically, when a predetermined time elapses from when the discharge of the rinse liquid is started, the rinse liquid valve 51 is closed. The supply of the rinse liquid to the substrate W is thereby stopped. Then, in a state where the facing member 6 is positioned at the processing position, the replacing liquid valve 53 is opened. The replacing liquid is thereby supplied (discharged) from the central nozzle 12 toward the central region of the upper surface of the substrate W in the rotating state (replacing liquid supplying step, replacing liquid discharging step).

Before the discharge of the replacing liquid is started, the guard elevating/lowering unit 74 may move at least one of the guards 71 vertically to switch the guard 71 that receives the liquid expelled from the substrate W.

In the replacing step, the substrate W is rotated at a predetermined replacing speed. The replacing speed is, for example, 300 rpm. In the present preferred embodiment, the rotational speed of the substrate W in the rinsing step and the rotational speed of the substrate W in the replacing speed are both 300 rpm. However, the substrate W may be rotated at a low speed in a predetermined period before the rinsing step ends and in a predetermined period after the replacing step starts. Specifically, the rotational speed of the substrate W may be changed to a low speed, for example, of 10 rpm before the rinsing step ends and may be changed to 300 rpm after the replacing step is started.

The replacing liquid discharged from the central nozzle 12 lands on the upper surface of the substrate W in the rotating state and thereafter flows outward along the upper surface of the substrate W due to a centrifugal force. The replacing liquid is thus supplied to the entire upper surface of the substrate W and a liquid film of the replacing liquid that covers the entire upper surface of the substrate W is formed.

Next, after the rinse liquid on the substrate W has been replaced by the replacing liquid, the sublimable-substance-containing liquid film forming step (step S5) of supplying the sublimable-substance-containing liquid to the upper surface of the substrate W to form a liquid film 100 (sublimable-substance-containing liquid film) of the sublimable-substance-containing liquid on the substrate W is performed.

Specifically, when a predetermined time elapses from when the discharge of the replacing liquid is started, the replacing liquid valve 53 is closed. The supply of the replacing liquid to the substrate W is thereby stopped. Then, in a state where the facing member 6 is positioned at the processing position, the sublimable-substance-containing liquid valve 52 is opened. The sublimable-substance-containing liquid is thereby supplied (discharged) from the central nozzle 12 toward the central region of the upper surface of the substrate Win the rotating state as shown in FIG. 5A.

Before the discharge of the sublimable-substance-containing liquid is started, the guard elevating/lowering unit 74 may move at least one of the guards 71 vertically to switch the guard 71 that receives the liquid expelled from the substrate W.

Rotation of the substrate W is continued even in the sublimable-substance-containing liquid film forming step. That is, the substrate rotating step is executed in parallel to the sublimable-substance-containing liquid film forming step. During discharge of the sublimable-substance-containing liquid, the substrate W is rotated at a predetermined supplying rotational speed. The supplying rotational speed is, for example, 300 rpm.

The sublimable-substance-containing liquid discharged from the central nozzle 12 lands on the upper surface of the substrate W in the rotating state and thereafter flows outward along the upper surface of the substrate W due to a centrifugal force. The sublimable-substance-containing liquid is thus supplied to the entire upper surface of the substrate W and the liquid film 100 of the sublimable-substance-containing liquid that covers the entire upper surface of the substrate W is formed. The central nozzle 12 thus functions as a sublimable-substance-containing liquid film forming unit that forms the liquid film 100 of the sublimable-substance-containing liquid on the upper surface of the substrate W.

Next, the film thinning step (step S6) of making a centrifugal force act on the liquid film 100 of the sublimable-substance-containing liquid to remove the sublimable-substance-containing liquid from the upper surface of the substrate W and thereby thin the liquid film 100 of the sublimable-substance-containing liquid is executed.

Specifically, when a predetermined time elapses from when the discharge of the sublimable-substance-containing liquid is started, the sublimable-substance-containing liquid valve 52 is closed. The supply of the sublimable-substance-containing liquid to the substrate W is thereby stopped. The facing member elevating/lowering unit 61 then moves the facing member 6 to the upper position.

As shown in FIG. 5B, at substantially the same time as stopping the discharge of the sublimable-substance-containing liquid, the rotational speed of the substrate W is changed to a film thinning rotational speed. The film thinning rotational speed is, for example, 500 rpm.

A film thickness of the liquid film 100 of the sublimable-substance-containing liquid at end of the film thinning step varies according to the rotational speed of the substrate W (setting value of the film thinning rotational speed) and time during which the film thinning step is executed. For example, the film thickness of the liquid film 100 of the sublimable-substance-containing liquid at the end of the film thinning step when the film thinning rotational speed is set to 750 rpm would be small in comparison to that when the film thinning rotational speed is set to 500 rpm.

The film thinning rotational speed and duration of the film thinning step are adjusted to make the film thickness of the liquid film 100 of the sublimable-substance-containing liquid at the end of the film thinning step a desired film thickness. That is, the film thinning step is also a film thickness adjusting step of adjusting the film thickness of the liquid film 100 of the sublimable-substance-containing liquid.

Although the film thickness of the liquid film 100 after the film thinning is far thinner than a thickness of the substrate W, in FIG. 5B, it is illustrated exaggeratingly (such as to be about the same as the thickness of the substrate W) for convenience of description (the same applies to FIG. 5C).

Next, the transition state film forming step (step S7) of evaporating the solvent from the liquid film 100 of the sublimable-substance-containing liquid to form a transition state film 101 on the upper surface of the substrate W is executed.

Although details shall be described later, inside the transition state film 101, the solids of the sublimable substance are in a pre-crystal transition state before crystallization. Inside the transition state film 101, the solids of the sublimable substance and the solvent in which the sublimable substance is dissolved are present mixedly.

Specifically, in the transition state film forming step, when a predetermined time elapses from when the film thinning step is started, the rotational speed of the substrate W is changed from the film thinning rotational speed to a predetermined transition state film forming rotational speed as shown in FIG. 5C. The transition state film forming rotational speed is, for example, 100 rpm. The transition state film forming rotational speed is lower than the film thinning rotational speed. The transition state film forming step is started with deceleration of the rotation of the substrate W as a trigger.

In the transition state film forming step, splashing of the sublimable-substance-containing liquid from the upper surface of the substrate W is suppressed because the rotational speed of the substrate W is comparatively low. The sublimable-substance-containing liquid can thus be prevented from being eliminated completely from the upper surface of the substrate W. The solvent can thus be evaporated from the liquid film 100 of the sublimable-substance-containing liquid while maintaining the liquid film 100 on the substrate W.

On the other hand, due to the rotation of the substrate W, a gas stream directed toward a peripheral edge side of the substrate W from a rotation center side of the substrate W is generated in an atmosphere in a vicinity of the upper surface of the substrate W. An amount of the solvent in a gaseous state inside the atmosphere in the vicinity of the upper surface of the substrate W is reduced and evaporation of the solvent from the liquid film 100 of the sublimable substance on the upper surface of the substrate W is promoted. By the solvent evaporating, solids of the sublimable substance are formed inside the liquid film 100 and, before long, the transition state film 101 is formed as shown in FIG. 5D.

Next, the transition state film removing step (step S8) of sublimating the solids of the sublimable substance on the substrate W while maintaining the solids of the sublimable substance inside the transition state film 101 in the pre-crystal transition state to remove the transition state film 101 from the upper surface of the substrate W is executed.

Specifically, the facing member elevating/lowering unit 61 moves the facing member 6 to the lower position as shown in FIG. 5E. The rotational speed of the substrate W is then changed to a predetermined sublimating rotational speed. The predetermined sublimating rotational speed is, for example, 300 rpm.

Here, the distance between the upper surface of the substrate W and the facing surface 6a when the facing member 6 is positioned at the lower position is set, for example, to 1 mm. In FIG. 5E, this is illustrated exaggeratingly (such as to be greater than the thickness of the substrate W) for convenience of description (the same applies to FIG. 5F and FIG. 5G).

Then, in the state where the facing member 6 is positioned at the lower position, the first gas valve 54 and the second gas valve 55 are opened. Thereby, the gas, such as nitrogen gas, etc., is blown toward the central region of the upper surface of the substrate W from the opening 6b of the facing member 6. The first gas flow control valve 58 is adjusted such that the flow rate of the gas discharged from the central nozzle 12 is a predetermined first gas flow rate. The first gas flow rate is, for example, 150 L/min. The second gas flow control valve 59 is adjusted such that the flow rate of the gas discharged from the gas flow passage 65 is a predetermined second gas flow rate. The second gas flow rate is, for example, 50 L/min. A total of the flow rates of the gas blown toward the upper surface of the substrate W in the transition state film removing step is referred to as the blowing-on flow rate. The blowing-on flow rate is thus, for example, 200 L/min.

The solvent and the sublimable substance in the gaseous states are eliminated from inside the atmosphere in the vicinity of the transition state film 101 at the central region of the upper surface of the substrate W by the gas blown onto the central region of the upper surface of the substrate W. Sublimation of the solids of the sublimable substance and the evaporation of the solvent are thus promoted at the central region of the upper surface of the substrate W (sublimating step, blowing-on sublimating step, blowing-on evaporating step). The central nozzle 12 and the gas flow passage 65 function as a sublimating unit.

By the sublimation of the solids of the sublimable substance and the evaporation of the solvent, the transition state film 101 is gradually thinned at the central region of the upper surface of the substrate W and, before long, the transition state film 101 at the central region of the upper surface of the substrate W disappears. A dry region D in which the upper surface of the substrate W is dry is thereby formed at the central region of the upper surface of the substrate W (dry region forming step). In plan view, the dry region D is of a circular shape centered at the rotation center of the upper surface of the substrate W.

Thereafter, by continuing the blowing of the gas onto the central region of the upper surface of the substrate W, the dry region D is enlarged as shown in FIG. 5F (dry region enlarging step). Specifically, the gas blown onto the central region of the upper surface of the substrate W forms a gas stream F that spreads radially toward the peripheral edge of the substrate W. By the gas stream F reaching a peripheral edge of the dry region D, the sublimation of the solids of the sublimable substance and the evaporation of the solvent inside the transition state film 101 are promoted at the peripheral edge of the dry region D. Thereby, the dry region D spreads while maintaining the circular shape centered at the rotation center of the upper surface of the substrate W in plan view.

Eventually, by the dry region D being enlarged further, the peripheral edge of the dry region D reaches the peripheral edge of the substrate W and the transition state film 101 disappears. In other words, the dry region D spreads across an entirety of the upper surface of the substrate W.

The transition state film 101 can thus be eliminated from the entire upper surface of the substrate W to dry the upper surface of the substrate W while maintaining a state in which the solids of the sublimable substance are not crystallized (sublimable-substance-containing liquid film eliminating step, substrate upper surface drying step).

A time from when the transition state film forming step is started to when the transition state film removing step is started (transition state film forming time) is required to be shorter than a time required for crystals of the sublimable substance to form from when the transition state film forming step is started (crystallization time).

The crystallization time can be measured visually. When the solids of the sublimable substance crystallize, the upper surface of the substrate W becomes more whitely clouded than in a state where the liquid film 100 or the transition state film 101 is present on the substrate W. The crystallization of the solids of the sublimable substance can thus be checked by checking a color of the upper surface of the substrate W. A crystallization time measuring step of measuring the crystallization time by imaging the upper surface of the substrate W using an imaging apparatus (not shown) may thus be executed in parallel to the transition state film forming step.

The transition state film forming time is preferably longer than half the crystallization time. If so, the transition state film removing step can be executed in a state where the solids of the sublimable substance are suitably present inside the transition state film. The transition state film forming time is more preferably a time of a length of ⅔rd the crystallization time.

Next, the lower surface rinsing step (step S9) of cleaning the lower surface of the substrate W while maintaining a state in which the upper surface of the substrate W is dry is executed.

Specifically, after the upper surface of the substrate W has been dried, the heating medium valve 56A is opened while maintaining the blowing of the gas onto the upper surface of the substrate W. The heating medium is thereby discharged toward the central region of the lower surface of the substrate W from the lower surface nozzle 13 as shown in FIG. 5G. The opening degree of the heating medium flow control valve 56B is adjusted such that the flow rate of the heating medium discharged from the lower surface nozzle 13 is set to a predetermined lower surface rinsing flow rate. The facing member 6 is maintained at the lower position.

The heating medium discharged from the lower surface nozzle 13 lands on the lower surface of the substrate Win the rotating state and thereafter flows outward along the lower surface of the substrate W due to a centrifugal force. Thereby, the heating medium spreads across the entire lower surface of the substrate W and the lower surface of the substrate W is cleaned.

While the lower surface of the substrate W is being cleaned by the heating medium, the blowing of the gas onto the upper surface of the substrate W is continued and the gas stream F directed from the central region of the upper surface of the substrate W toward the peripheral edge of the substrate W is formed. The heating medium that splashes back from the guard 71 can be pushed back toward the guard 71 by the gas stream F. By the gas stream F, the heating medium can be suppressed from flowing around from the lower surface of the substrate W to the upper surface via the peripheral edge of the substrate W. Attachment of the heating medium to the upper surface of the substrate W can thus be suppressed.

The substrate W can be heated by using the heating medium in the lower surface rinsing step as in the present preferred embodiment. Evaporation of a slight amount of liquid remaining on the upper surface of the substrate W can thus be promoted.

Before the discharge of the heating medium is started, the guard elevating/lowering unit 74 may move at least one of the guards 71 vertically to switch the guard 71 that receives the liquid expelled from the substrate W.

Next, the spin drying step (step S10) of rotating the substrate W at high speed to dry the upper surface of the substrate W and the lower surface of the substrate W is executed.

Specifically, in a state where the facing member 6 is maintained at the lower position and the blowing of the gas onto the upper surface of the substrate W is maintained, the heating medium valve 56A is closed. The rotational speed of the substrate W is then changed to a predetermined spin drying speed. The spin drying speed is, for example, 1500 rpm. By the spin drying step, a slight amount of liquid remaining on the upper surface of the substrate W and the heating medium attached to the lower surface of the substrate W are removed.

After the spin drying step, the rotation of the substrate W is stopped. The guard elevating/lowering unit 74 moves all of the guard 71 to the lower positions. The first gas valve 54 and the second gas valve 55 are then closed. The facing member elevating/lowering unit 61 then moves the facing member 6 to the upper position.

The transfer robot CR enters into the processing unit 2, lifts up the processed substrate W from the chuck pins 20 of the spin chuck 5 and carries it outside the processing unit 2 (step S11). The substrate W is transferred from the transfer robot CR to the transfer robot IR and housed in a carrier C by the transfer robot IR.

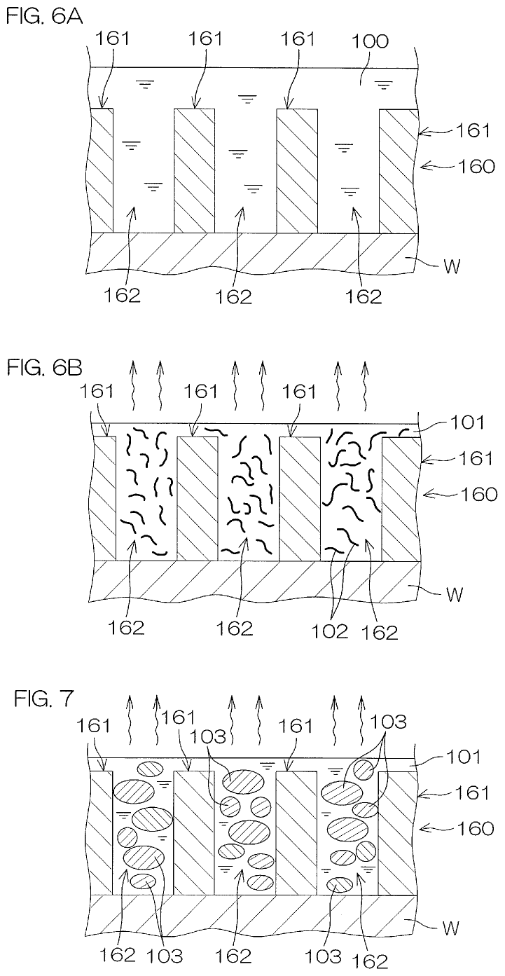

FIG. 6A and FIG. 6B are schematic views for describing conditions of the upper surface of the substrate W in the transition state film forming step (step S7).

A fine pattern 160 is formed on the upper surface of the substrate Won which the substrate processing is executed. The pattern 160 includes fine projecting structural bodies 161 formed on the upper surface of the substrate W and recesses (grooves) 162 formed between adjacent structural bodies 161. If the structural bodies 161 are cylindrical, recesses are formed at inner sides thereof.

Each structural body 161 may include a resistor film or may include a conductor film. Also, the structural body 161 may be a laminated film with which are plurality of films are laminated.

An aspect ratio of the pattern 160 is, for example, 10 to 50. A width of the structural body 161 may be approximately 10 nm to 45 nm and a mutual interval between the structural bodies 161 (may also be referred to as the mutual interval between the patterns 160) may be approximately 10 nm to several μm. A height of each structural body 161 may, for example, be approximately 50 nm to 5 μm.

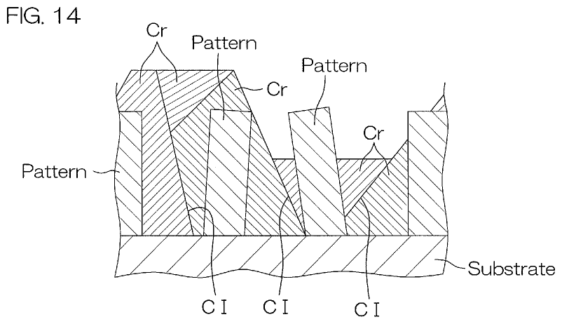

The conditions of the upper surface of the substrate W immediately after the end of the film thinning step (immediately after the start of the transition state film forming step) are shown in FIG. 6A. When the solvent evaporates from the liquid film 100 in the state shown in FIG. 6A, the solids of the sublimable substance precipitate and the transition state film 101 is formed as shown in FIG. 6B. The solids of the sublimable substance are, for example, amorphous solids 102. Inside the amorphous solids 102, molecules of the sublimable substance are arranged irregularly. Therefore, unlike crystals Cr of the sublimable substance (see FIG. 14), the amorphous solids 102 do not have a clear interface.

On the other hand, the solids of the sublimable substance may be microcrystalline solids 103 as shown in FIG. 7. As in crystallized solids of the sublimable substance, the molecules of the sublimable substance inside the microcrystalline solids 103 are arranged regularly.

Here, that the solids of the sublimable substance crystallize means that adjacent crystals grow to a degree of mutually forming a crystal interface. Specifically, when the crystals of the sublimable substance grow to a size not less than the mutual interval between the structural bodies 161 of the pattern 160, crystal interfaces are formed mutually between adjacent crystals.

The crystallization time is the time required for crystals that have grown to a size not less than the mutual interval between the structural bodies 161 of the pattern 160 begin to be formed from a point at which the rotational speed of the substrate W is changed to the transitional state film forming rotation speed.

On the other hand, a crystal interface is not formed between adjacent microcrystalline solids 103 and their size is less than the mutual interval between the structural bodies 161 of the pattern 160. The microcrystalline solids 103 are crystals of a size such that they do not surface-contact each other. Shear stress is thus not generated mutually between the microcrystalline solids 103. Specifically, the microcrystalline solids 103 are crystals of the sublimable substance of a size smaller than the mutual interval between the structural bodies 161 of the pattern 160. A “state in which the microcrystalline solids 103 do not surface-contact each other” includes a state in which the microcrystalline solids 103 do not contact each other at all. The “state in which the microcrystalline solids 103 do not surface-contact each other” also includes a state in which, although the microcrystalline solids 103 hardly contact each other, the microcrystalline solids 103 are in contact to a degree where a shear stress is not generated between each other.

Although not illustrated, a case where the amorphous solids 102 and the microcrystalline solids 103 are present mixedly inside the transition state film 101 is also possible.

According to the first preferred embodiment, the transition state film 101 is formed on the upper surface of the substrate W by evaporating the solvent from the liquid film 100 of the sublimable-substance-containing liquid and precipitating the solids (the amorphous solids 102 or the microcrystalline solids 103) of the sublimable substance in the pre-crystal transition state (transition state film forming step). The solids inside the transition state film 101 are then sublimated while being maintained in the pre-crystal transition state (sublimating step). The transition state film 101 is thereby removed from the upper surface of the substrate W (transition state film removing step). The solvent remaining on the substrate W also evaporates when the solids of the sublimable substance are sublimated. The upper surface of the substrate W is thereby dried.

The transition state film 101 is thus removed from the upper surface of the substrate W without passing through a state in which the solids of the sublimable substance are crystallized. Collapse of the pattern 160 on the substrate W can thus be lessened by reducing the influence of stress due to the crystallization of the sublimable substance.

In detail, the solids of the sublimable substance inside the transition state film 101 are the amorphous solids 102 or the microcrystalline solids 103 and therefore do not have a crystal interface CI (see FIG. 14) that accompanies stress. The solids of the sublimable substance can thus be sublimated without receiving influence of stress generated in a vicinity of a crystal interface CI when the solids of the sublimable substance crystallize. The collapse of the pattern 160 can thus be suppressed.

If the transition state film forming time is too short, the amount of the solvent remaining on the surface of the substrate at a point at which the transition state film removing step is started would be comparatively large. Therefore, when the solids of the sublimable substance are sublimated, surface tension of the solvent on the surface of the substrate may act on the pattern 160 and the pattern 160 may collapse. Oppositely, if the transition state film forming time is too long, the solids of the sublimable substance would be sublimated in the crystallized state. The pattern 160 may thus collapse due to a force that acts on the pattern 160 due to the stress generated at the crystal interface CI.

Thus, if the transition state film forming time is longer than half the crystallization time and shorter than the crystallization time, the crystallization of the solids of the sublimable substance can be avoided while sufficiently reducing the amount of the solvent remaining on the upper surface of the substrate W at the start of the transition state film removing step. The collapse of the pattern 160 on the substrate W can thereby be lessened.

Especially, if the transition state film forming time is a time of a length of ⅔rd the crystallization time, the amount of the solvent remaining on the upper surface of the substrate W at the start of the transition state film removing step can be reduced as much as possible while avoiding the crystallization of the solids of the sublimable substance. The collapse of the pattern on the substrate W can thus be lessened further.

Also, according to the first preferred embodiment, the film thinning step of thinning the liquid film 100 of the sublimable-substance-containing liquid is executed. Thus, in the transition state film forming step executed after the film thinning step, the transition state film 101 can be formed by evaporating the solvent from the thinned liquid film 100 of the sublimable-substance-containing liquid. The transition state film 101 can thus be formed quickly.

Also, according to the first preferred embodiment, the transition state film 101 is formed by evaporating the solvent mainly by the rotation of the substrate W. The solvent can thus be evaporated quickly from the liquid film 100 of the sublimable-substance-containing liquid. The transition state film 101 can thus be formed quickly.

Also, according to the first preferred embodiment, the substrate W is rotated in the film thinning step at the film thinning rotational speed (first rotational speed) that is a comparatively high speed. The sublimable-substance-containing liquid is thus eliminated quickly from the upper surface of the substrate W by the centrifugal force. Also, the film thickness of the liquid film 100 of the sublimable-substance-containing liquid on the upper surface of the substrate W is adjusted quickly. Then, in the transition state film forming step, the substrate W is rotated at the transition state film forming rotational speed (second rotational speed) that is a comparatively low speed. The centrifugal force acting on the liquid film 100 of the sublimable-substance-containing liquid on the upper surface of the substrate W can thereby be reduced. The solvent can thus be evaporated from the liquid film 100 to form the transition state film 101 quickly while maintaining the liquid film 100, in the state in which its film thickness was adjusted in the film thinning step, on the upper surface of the substrate W.

Also, with the first preferred embodiment, the solids (the amorphous solids 102 or the microcrystalline solids 103) of the sublimable substance on the upper surface of the substrate W are sublimated in the transition state film removing step by the blowing-on of the gas (blowing-on sublimating step). That is, the solids of the sublimable substance on the upper surface of the substrate W can be sublimated by a simple method of blowing-on of the gas.

### Second Preferred Embodiment

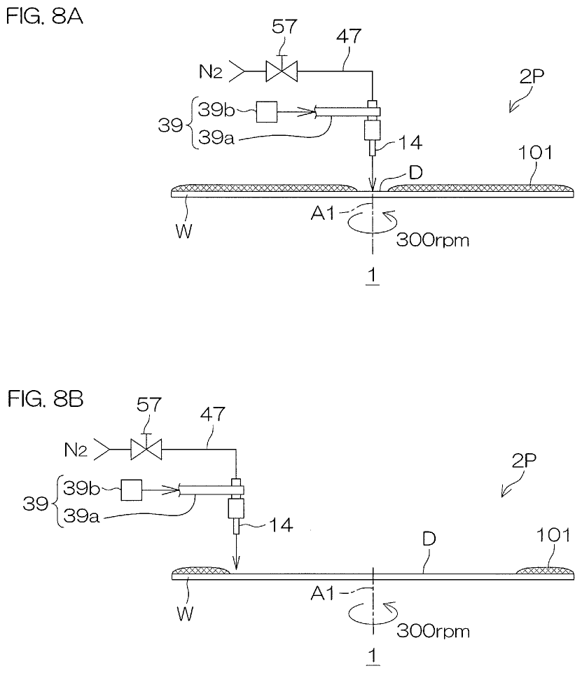

FIG. 8A and FIG. 8B are schematic views for describing conditions of the transition state film removing step (step S8) by the substrate processing apparatus 1 according to a second preferred embodiment of the present invention. In FIG. 8A and FIG. 8B, configurations that are the equivalent to the configurations shown in FIG. 1 to FIG. 7 described above are provided with the same reference symbols as in FIG. 1, etc., and description thereof shall be omitted.

A point by which a processing unit 2P according to the second preferred embodiment differs mainly from the processing unit 2 (see FIG. 2) of the first preferred embodiment is that the processing unit 2P includes a moving gas nozzle 14 that is movable at least in a horizontal direction and is capable of discharging a gas toward the upper surface of the substrate W.

The moving gas nozzle 14 is moved in the horizontal direction and in a vertical direction by a gas nozzle moving unit 39. The moving gas nozzle 14 is capable of moving between a center position and a home position (retreat position).

When positioned at the center position, the moving gas nozzle 14 faces the rotation center of the upper surface of the substrate W. When positioned at the home position, the moving gas nozzle 14 does not face the upper surface of the substrate W and is positioned outside the processing cup 7 in plan view. By moving in the vertical direction, the moving gas nozzle 14 can move close to the upper surface of the substrate W and retreat upward from the upper surface of the substrate W.

The gas nozzle moving unit 39 includes, for example, an arm 39a that supports the moving gas nozzle 14 and extends horizontally and an arm driving unit 39b that drives the arm 39a. The arm driving unit 39b includes a pivoting shaft (not shown) that is coupled to the arm 39a and extends along the vertical direction and a pivoting shaft driving unit (not shown) that elevates, lowers, and pivots the pivoting shaft.

The pivoting shaft driving unit swings the arm 39a by pivoting the pivoting shaft around a vertical pivoting axis. Further, the pivoting shaft driving unit elevates and lowers the pivoting shaft along the vertical direction to move the arm 39a up and down. The moving gas nozzle 14 moves in the horizontal direction and in the vertical direction in accordance with the swinging and elevation/lowering of the arm 39a.

The moving gas nozzle 14 is connected to a moving gas piping 47 that guides the gas to the moving gas nozzle 14. When a moving gas valve 57 interposed in the moving gas piping 47 is opened, the gas is discharged continuously downward from a discharge port of the moving gas nozzle 14.

The gas discharged from the moving gas nozzle 14 is an inert gas, for example, nitrogen gas (N₂), etc. The gas discharged from the moving gas nozzle 14 may be air.

The controller 3 according to the second preferred embodiment controls the moving gas valve 57 and the gas nozzle moving unit 39 in addition to the objects controlled by the controller 3 according to the first preferred embodiment (see FIG. 3).

The same substrate processing as that of the flowchart shown in FIG. 4 is made possible with the substrate processing apparatus 1 according to the second preferred embodiment. In detail, the substrate processing according to the second preferred embodiment is substantially the same as the substrate processing according to the first preferred embodiment with the exception that the forming of the dry region D and the enlarging of the dry region D in the transition state film forming step (step S8) are mainly performed by the blowing-on of the gas from the moving gas nozzle 14. The transition state film forming step in the substrate processing according to the second preferred embodiment shall be described below.

As shown in FIG. 8A, the gas nozzle moving unit 39 moves the moving gas nozzle 14 to the center position. The moving gas valve 57 is opened in the state where the moving gas nozzle 14 is positioned at the center position. The gas is thereby discharged toward the upper surface of the substrate W from the discharge port of the moving gas nozzle 14 (gas discharging step). The gas discharged from the moving gas nozzle 14 is blown onto the central region of the upper surface of the substrate W.

The solvent and the sublimable substance in the gaseous states are eliminated from inside the atmosphere in the vicinity of the transition state film 101 at the central region of the upper surface of the substrate W by the gas blown onto the central region of the upper surface of the substrate W. The sublimation of the sublimable substance and the evaporation of the solvent are thus promoted at the central region of the upper surface of the substrate W (sublimating step, blowing-on sublimating step, blowing-on evaporating step). The moving gas nozzle 14 functions as a sublimating unit.

By the sublimation of the sublimable substance and the evaporation of the solvent, the transition state film 101 is gradually thinned at the central region of the upper surface of the substrate W and, before long, the transition state film 101 at the central region of the upper surface of the substrate W disappears. The dry region D in which the upper surface of the substrate W is dry is thereby formed at the central region of the upper surface of the substrate W (dry region forming step). In plan view, the dry region D is of a circular shape centered at the rotation center of the upper surface of the substrate W.

Thereafter, as shown in FIG. 8B, the gas nozzle moving unit 39 moves the moving gas nozzle 14 such that a position on the substrate W onto which the gas is blown (gas blowing-on position) moves toward the peripheral edge region of the upper surface of the substrate W. The gas discharged from the moving gas nozzle 14 is thereby blown onto an inner peripheral edge of the transition state film 101 and the sublimation of the solids of the sublimable substance and the evaporation of the solvent are promoted at the inner peripheral edge of the transition state film 101.

However, the gas blowing-on position is preferably positioned at a position of the substrate W overlapping with the peripheral edge of the dry region D or further toward the rotation center side of the substrate W than the peripheral edge of the dry region D.

Moreover, the substrate W is rotating at the predetermined sublimating rotational speed and therefore the gas blowing-on position undergoes relative movement in a rotation direction of the substrate W. The gas is thus blown on uniformly across an entire circumference in the rotation direction at the inner peripheral edge of the transition state film 101. Thereby, the dry region D spreads while maintaining the circular shape centered at the rotation center of the upper surface of the substrate W in plan view.

Eventually, by the dry region D being enlarged further, the peripheral edge of the dry region D reaches the peripheral edge of the substrate W and the transition state film 101 disappears. That is, the dry region D spreads across the entirety of the upper surface of the substrate W. In other words, the transition state film 101 is eliminated from the entire upper surface of the substrate W and the upper surface of the substrate W is dried (sublimable-substance-containing liquid film eliminating step, substrate upper surface drying step). Thereafter, as in the substrate processing according to the first preferred embodiment, the lower surface rinsing step (step S9) is started.

According to the second preferred embodiment, the same effects as those of the first preferred embodiment are exhibited.

According to the second preferred embodiment, the dry region D is formed by the blowing of the gas onto the central region of the upper surface of the substrate W. Thereafter, the gas blowing-on position is moved toward the peripheral edge region of the upper surface of the substrate W. A blowing-on force of the gas can thus be made to act efficiently on the solids of the sublimable substance inside the transition state film 101 in a vicinity of the peripheral edge of the dry region D. The dry region D can thus be enlarged quickly. Consequently, a difference in time from when formation of the transition state film 101 is started to when the solids of the sublimable substance sublimate between the central region of the upper surface of the substrate W and the peripheral edge region of the upper surface of the substrate W can be reduced. The collapse of the pattern 160 can thus be lessened across the entirety of the upper surface of the substrate W.

The present invention is not restricted to the preferred embodiments described above and can be implemented in yet other modes.

For example, in the preferred embodiments described above, the chemical liquid, the rinse liquid, the sublimable-substance-containing liquid, and the replacing liquid are discharged from the central nozzle 12. However, the respective liquids may be discharged from individual nozzles instead. For example, a chemical liquid nozzle, a rinse liquid nozzle, a sublimable-substance-containing liquid nozzle, and a replacing liquid nozzle may be provided as moving nozzles. Further, the chemical liquid nozzle, the rinse liquid nozzle, the sublimable-substance-containing liquid nozzle, and the replacing liquid nozzle may be provided separately of the central nozzle 12 as fixed nozzles that are fixed in position in the horizontal direction and the vertical direction.

Also, for example, the gas discharged from the central nozzle 12, the gas flow passage 65, and the moving gas nozzle 14 may be a high temperature gas, such as a high temperature inert gas, high temperature air, etc. In this case, the evaporation of the solvent and the sublimation of the solids of the sublimable substance can be promoted.

Also, in the lower surface rinsing step, if there is no need to heat the substrate W, the liquid discharged from the lower surface nozzle 13 is not required to be the heating medium and may be the rinse liquid.

Also, with each of the preferred embodiments described above, in the transition state film removing step, the transition state film 101 is removed from the upper surface of the substrate W by forming the dry region D at the central region of the substrate W and thereafter enlarging the dry region D. However, the transition state film 101 may instead be thinned uniformly across the entirety of the upper surface of the substrate W and then removed from the upper surface of the substrate W. With a substrate processing with which a gas is not blown onto the central region of the upper surface of the substrate W but with which an interval between the upper surface of the substrate W and the facing surface 6a is filled with a gas, the solvent can be evaporated readily from the entire upper surface of the substrate W.

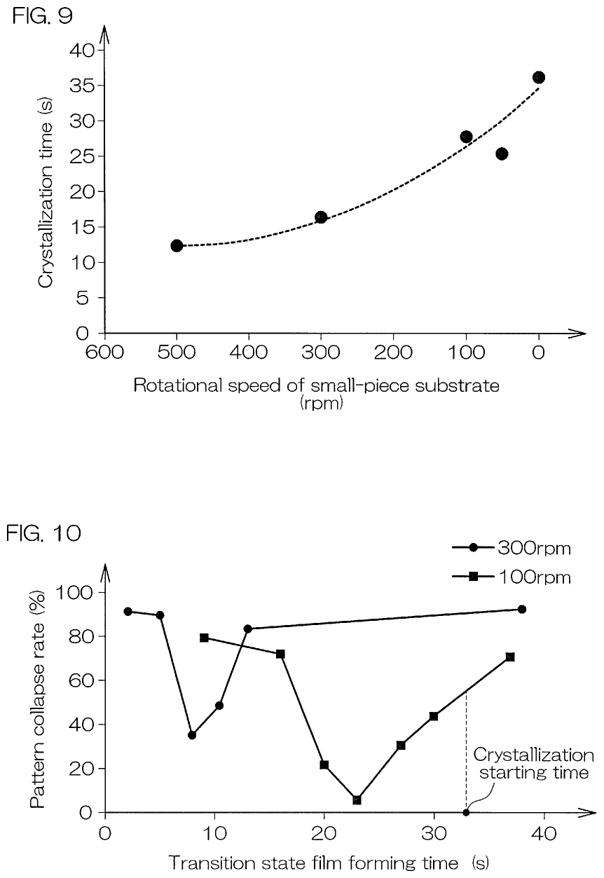

In the following, results of experiments performed to examine pattern collapse suppressing effects by the present invention shall be described using FIG. 9 to FIG. 13B.

In the experiments of FIG. 9 and FIG. 10, the following preprocessing was applied using substrates of small piece shape (small-piece substrates). In the preprocessing, each small-piece substrate was immersed in IPA and thereafter, the small-piece substrate was immersed in a sublimable-substance-containing liquid. Thereafter, the film thinning step, the transition state film forming step, and the transition state film removing step were performed on the small-piece substrate. Thereafter, the small-piece substrate was heated at 60° C. for 10 seconds and thereafter, nitrogen was blown onto a surface of the small-piece substrate at a flow rate of 40 L/min for 60 seconds. Thereafter, pattern collapse rate was measured using a scanning electron microscope (SEM).

FIG. 9 shows the results of an experiment that was performed to examine a relationship of the transition state film forming rotational speed of the small-piece substrate in the transition state film forming step and the crystallization time. In this experiment, the small-piece substrate was rotated at 500 rpm for 2 seconds in the film thinning step. In this experiment, in the transition state film removing step, nitrogen gas was blown at a flow rate of 40 L/min for 60 seconds onto the small-piece substrate while rotating the small-piece substrate at 300 rpm for 60 seconds. In this experiment, a plurality of the preprocessing differing in the transition state film forming rotational speed were respectively performed on a plurality of the small-piece substrates. Measurement of the crystallization time was performed by visually observing the crystallization of the solids of the sublimable substance during the transition state film forming step of each small-piece substrate.

FIG. 9 is a graph showing the relationship of the transition state film forming rotational speed and the crystallization time. As shown in FIG. 9, it was found from this experiment that the faster the transition state film forming rotational speed, the shorter the crystallization time.

FIG. 10 is a graph showing results of an experiment performed to examine a relationship of the transition state film forming time and the pattern collapse rate. In this experiment, each small-piece substrate was rotated at 500 rpm for 2 seconds in the film thinning step. In this experiment, in the transition state film removing step, nitrogen gas was blown at a flow rate of 40 L/min for 60 seconds onto the small-piece substrate while rotating the small-piece substrate at 300 rpm for 60 seconds. In this experiment, a plurality of the preprocessing differing in the transition state film forming rotational speed and the transition state film forming time were respectively performed on a plurality of the small-piece substrates.

FIG. 10 is a graph showing the relationship of the transition state film forming time and the pattern collapse rate. When the transition state film forming rotational speed was 100 rpm, the pattern collapse rate was reduced when the transition state film forming time was longer than half the crystallization time and shorter than the crystallization time. In particular, the pattern collapse rate was reduced dramatically with the transition state film forming time being a time of a length of ⅔rd the crystallization time.

Further, when the transition state film forming rotational speed was 100 rpm, a range of the transition state film forming time with which the pattern collapse rate was decreased was wider than that when the transition state film forming rotational speed was 300 rpm. It is thus inferred that an adjustment range (margin) of the transition state film forming time can be widened by slowing down the transition state film forming rotational speed.

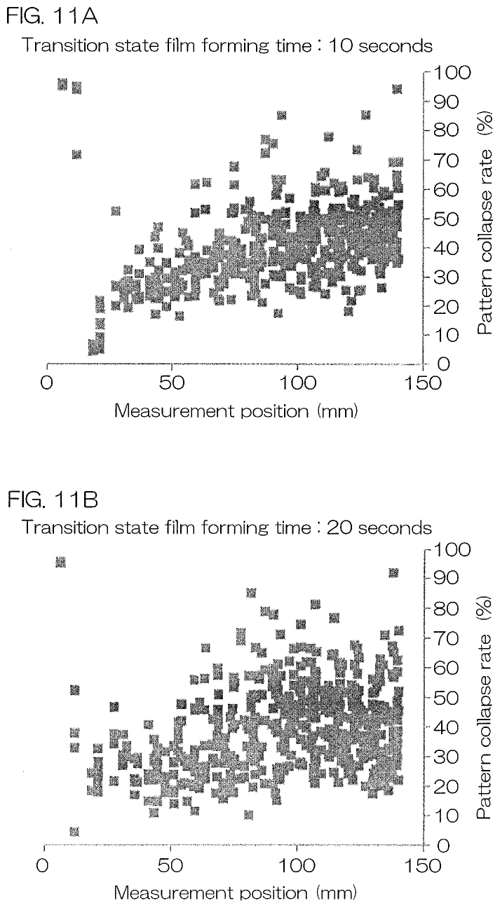

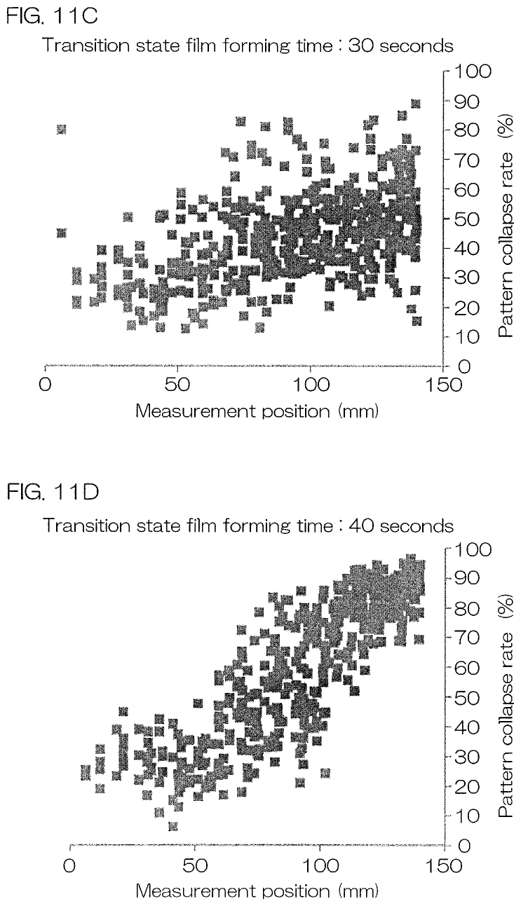

In each of the experiments shown in FIG. 11A to FIG. 13B, the substrate processing according to the first preferred embodiment was performed using a circular substrate of 150 mm radius and thereafter, the pattern collapse rates were measured by using the SEM.

FIG. 11A to FIG. 11D are graphs showing the results of an experiment performed to examine a relationship of the transition state film forming time and the pattern collapse rate. In this experiment, a plurality of the substrate processing differing in the transition state film forming time were respectively performed on a plurality of the substrates. The collapse rates of the pattern on each substrate after being subject to the substrate processing were then measured at a plurality of locations (300 locations) on the substrate.

In this experiment, each substrate was rotated at 500 rpm for 2 seconds in the film thinning step. Also, in this experiment, in the transition state film removing step, nitrogen gas was blown at a flow rate of 100 L/min onto the substrate from the central nozzle 12 and the substrate was rotated at 300 rpm. In this experiment, the substrate was rotated at 100 rpm in the transition state film forming step.

In the graphs shown in FIG. 11A to FIG. 11D, the abscissa indicates a measurement position (distance to a measurement location from the rotation center of the substrate) at the upper surface of the substrate and the ordinate indicates the collapse rate of the pattern at each measurement location.

FIG. 11A is a graph showing the pattern collapse rates at the plurality of locations on the substrate when the transition state film forming time was set to 10 seconds. The average value of the pattern collapse rates on the substrate when the transition state film forming time was set to 10 seconds was 41%. FIG. 11B is a graph showing the pattern collapse rates at the plurality of locations on the substrate when the transition state film forming time was set to 20 seconds. The average value of the pattern collapse rates on the substrate when the transition state film forming time was set to 20 seconds was 39.1%. FIG. 11C is a graph showing the pattern collapse rates at the plurality of locations on the substrate when the transition state film forming time was set to 30 seconds. The average value of the pattern collapse rates on the substrate when the transition state film forming time was set to 30 seconds was 43.9%. FIG. 11D is a graph showing the pattern collapse rates at the plurality of locations on the substrate when the transition state film forming time was set to 40 seconds. The average value of the pattern collapse rates on the substrate when the transition state film forming time was set to 40 seconds was 61.4%.

The result that the pattern collapse rate when the transition state film forming time was set to 10 seconds, 20 seconds, or 30 seconds was low in comparison to that when the transition state film forming time was set to 40 seconds was thus obtained. From this result, it is inferred that, when the transition state film forming time was set to 40 seconds, crystals of the sublimable substance were formed on the upper surface of the substrate at the start of the transition state film removing step. Oppositely, it is inferred that, when the transition state film forming time was set to 10 seconds, 20 seconds, or 30 seconds, crystals of the sublimable substance were not formed on the upper surface of the substrate.

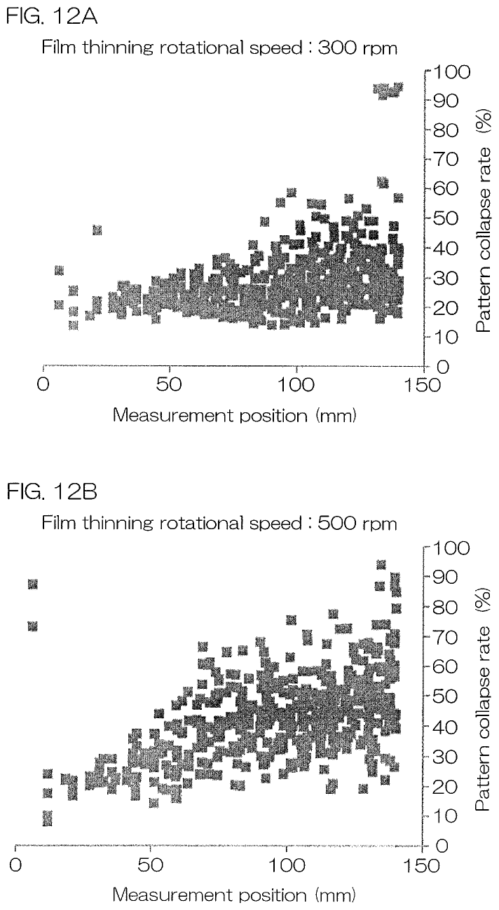

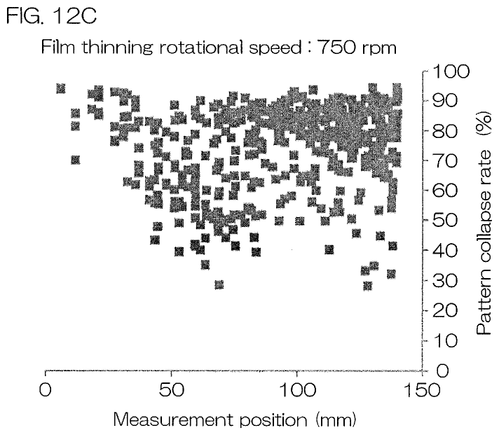

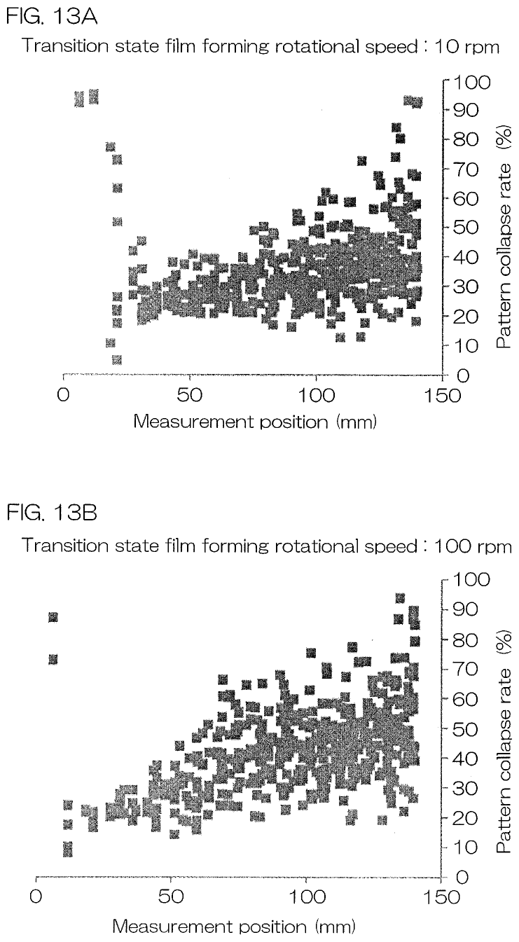

FIG. 12A to FIG. 12C are graphs showing results of an experiment performed to examine a relationship of the film thinning rotational speed and the pattern collapse rate. In this experiment, a plurality of the substrate processing differing in the film thinning rotational speed were respectively performed on a plurality of the substrates. Thereafter, the collapse rates of the pattern on each substrate after being subject to the substrate processing were measured at a plurality of locations (300 locations) on the substrate.

In this experiment, in the transition state film forming state, each substrate was rotated at 100 rpm and the transition state film forming time was set to a time of a length of ⅔rd the crystallization time. Also, in this experiment, in the transition state film removing step, the flow rate of the nitrogen gas discharged from the central nozzle 12 was set to 150 L/min, the flow rate of the nitrogen gas discharged from the gas flow passage 65 was set to 50 L/min, and the rotational speed of the substrate was set to 300 rpm. Also, in this experiment, the substrate was rotated at the film thinning rotational speed for 2 seconds in the film thinning step.

In the graphs shown in FIG. 12A to FIG. 12C, the abscissa indicates the measurement position (distance to the measurement location from the rotation center of the substrate) at the upper surface of the substrate and the ordinate indicates the collapse rate of the pattern at each measurement location.

FIG. 12A is a graph showing the pattern collapse rates at the plurality of locations on the substrate when the film thinning rotational speed was set to 300 rpm. The average value of the pattern collapse rates on the substrate when the film thinning rotational speed was set to 300 rpm was 28.7%. FIG. 12B is a graph showing the pattern collapse rates at the plurality of locations on the substrate when the film thinning rotational speed was set to 500 rpm. The average value of the pattern collapse rates on the substrate when the film thinning rotational speed was set to 500 rpm was 41.8%. FIG. 12C is a graph showing the pattern collapse rates at the plurality of locations on the substrate when the film thinning rotational speed was set to 750 rpm. The average value of the pattern collapse rates on the substrate when the film thinning rotational speed was set to 750 rpm was 77.3%.

The result that the pattern collapse rate when the film thinning rotational speed was set to 500 rpm or 300 rpm was low in comparison to that when the film thinning rotational speed was set to 750 rpm was thus obtained.

It is inferred that, with the substrate processing with which the film thinning rotational speed was set to 500 rpm or 300 rpm, the pattern collapse rate was low because the transition state film forming step was started in a state where the liquid film of the sublimable-substance-containing liquid was maintained at a sufficient thickness and the transition state film removing step was started before crystals of the sublimable substance formed on the upper surface of the substrate. It is inferred that, with the substrate processing with which the film thinning rotational speed was set to 750 rpm, the pattern collapse rate was high because surface tension acted on the pattern due to the liquid film of the sublimable-substance-containing liquid being thinned to a degree where a gas-liquid interface of the sublimable-substance-containing liquid was positioned lower than tips of the pattern.

FIG. 13A and FIG. 13B are graphs showing results of an experiment performed to examine a relationship of the transition state film forming rotational speed and the pattern collapse rate. In this experiment, a plurality of the substrate processing differing in the transition state film forming rotational speed were respectively performed on a plurality of the substrates. Thereafter, the collapse rates of the pattern on each substrate after being subject to the substrate processing were measured at a plurality of locations (300 locations) on the substrate.

In this experiment, the transition state film forming time was set to a time of a length of ⅔rd the crystallization time. Specifically, when the transition state film forming rotational speed was 10 rpm, the transition state film forming time was set to 40 seconds, and when the transition state film forming rotational speed was 100 rpm, the transition state film forming time was set to 25 seconds. Also, in this experiment, in the film thinning step, the film thinning rotational speed was set to 500 rpm and each substrate was rotated for 2 seconds. Also, in this experiment, in the transition state film removing step, the flow rate of the nitrogen gas discharged from the central nozzle 12 was set to 150 L/min, the flow rate of the nitrogen gas discharged from the gas flow passage 65 was set to 50 L/min, and the sublimating rotational speed was set to 300 rpm.

In the graphs shown in FIG. 13A and FIG. 13B, the abscissa indicates the measurement position (distance to the measurement location from the rotation center of the substrate) at the upper surface of the substrate and the ordinate indicates the collapse rate of the pattern at each measurement location.

FIG. 13A is a graph showing the pattern collapse rates at the plurality of locations on the substrate when the transition state film forming rotational speed was set to 10 rpm. The average value of the pattern collapse rates on the substrate when the transition state film forming rotational speed was set to 10 rpm was 36.2%. FIG. 13B is a graph showing the pattern collapse rates at the plurality of locations on the substrate when the transition state film forming rotational speed was set to 100 rpm. The average value of the pattern collapse rates on the substrate when the transition state film forming rotational speed was set to 100 rpm was 41.8%.

It was thus possible to sufficiently reduce the pattern collapse rate regardless of the transition state film forming rotational speed. As a reason for this, it is inferred that it was possible to start the sublimation before crystals of the sublimable substance were formed and after the solvent was evaporated sufficiently because the transition state film forming time was set to a time of a length of ⅔rd the crystallization time.

From the experiment results shown in FIG. 11A to FIG. 12C, it is inferred that the transition state film forming time (timing of the start of the transition state film removing step) and the film thickness of the liquid film of the sublimable-substance-containing liquid at the start of the transition state film forming step greatly influence the pattern collapse rate. From the experiment results shown in FIG. 13A and FIG. 13B, it is inferred that, by setting the transition state film forming time to a time of a length of ⅔rd the crystallization time, the pattern collapse rate can be reduced regardless of the transition state film forming rotational speed.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A substrate processing method comprising:
a sublimable-substance-containing liquid film forming step of supplying a sublimable-substance-containing liquid, which is a solution containing a sublimable substance changing from a solid to a gas without passing through a liquid state and a solvent dissolving the sublimable substance, to a surface of a substrate on which a pattern is formed, so that a liquid film of the sublimable-substance-containing liquid covering the surface of the substrate is formed on the surface of the substrate;
a transition state film forming step of evaporating the solvent from the liquid film to form solids of the sublimable substance, so that a transition state film, that is in a pre-crystal transition state before the solids of the sublimable substance crystallize, is formed on the surface of the substrate; and
a transition state film removing step of sublimating the solids of the sublimable substance on the surface of the substrate while maintaining the solids of the sublimable substance in the pre-crystal transition state, so that the transition state film from the surface of the substrate is removed.

2. The substrate processing method according to claim 1, wherein the solids of the sublimable substance inside the transition state film include amorphous solids.

3. The substrate processing method according to claim 1, wherein the solids of the sublimable substance inside the transition state film include microcrystalline solids.

4. The substrate processing method according to claim 1, wherein a transition state film forming time that is a time from when the transition state film forming step is started to when the transition state film removing step is started is longer than half of a crystallization time that is a time required until crystals of the sublimable substance form from when the transition state film forming step is started and is shorter than the crystallization time.

5. The substrate processing method according to claim 4, wherein the transition state film forming time is a time of a length of ⅔rd the crystallization time.

6. The substrate processing method according to claim 1, further comprising: a film thinning step of rotating the substrate around a vertical axis passing through a central part of the surface of the substrate to eliminate the sublimable-substance-containing liquid from the surface of the substrate to thin the liquid film before execution of the transition state film forming step.

7. The substrate processing method according to claim 1, wherein the transition state film forming step includes a step of rotating the substrate around a vertical axis passing through a central part of the surface of the substrate to evaporate the solvent in the liquid film to form the transition state film.

8. The substrate processing method according to claim 1, further comprising: a film thinning step of rotating the substrate at a predetermined first rotational speed around a vertical axis passing through a central part of the surface of the substrate to make a centrifugal force act on the liquid film on the surface of the substrate to thin the liquid film,
wherein the transition state film forming step includes a step of changing the rotational speed of the substrate to a predetermined second rotational speed lower than the first rotational speed to evaporate the solvent in the liquid film to form the transition state film after the film thinning step.

9. The substrate processing method according to claim 1, wherein the transition state film removing step includes a blowing-on sublimating step of blowing a gas onto the transition state film to sublimate the solids of the sublimable substance on the surface of the substrate.

10. The substrate processing method according to claim 9, wherein the blowing-on sublimating step includes a dry region forming step of blowing the gas onto a central region of the surface of the substrate to sublimate the solids of the sublimable substance to forma dry region at the central region of the surface of the substrate, and a dry region enlarging step of enlarging the dry region while moving a blowing-on position of the gas at the surface of the substrate toward a peripheral edge region of the surface of the substrate.

11. A substrate processing apparatus comprising:
a sublimable-substance-containing liquid supplying unit that supplies a sublimable-substance-containing liquid being a solution containing a sublimable substance changing from a solid to a gas without passing through a liquid state and a solvent dissolving the sublimable substance to a surface of a substrate;
a substrate rotating unit that rotates the substrate around a vertical axis passing through a central part of the surface of the substrate;
a sublimating unit that sublimates solids of the sublimable substance from the surface of the substrate; and
a controller that controls the sublimable-substance-containing liquid supplying unit, the substrate rotating unit, and the sublimating unit,
wherein the controller is programmed to execute a sublimable-substance-containing liquid film forming step of supplying the sublimable-substance-containing liquid from the sublimable-substance-containing liquid supplying unit to the surface of the substrate on which a pattern is formed, so that a liquid film of the sublimable-substance-containing liquid covering the surface of the substrate is formed on the surface of the substrate, a transition state film forming step of evaporating the solvent from the liquid film by the substrate rotating unit to form the solids of the sublimable substance, so that a transition state film, that is in a pre-crystal transition state before the solids of the sublimable substance crystallize, is formed on the surface of the substrate, and a transition state film removing step of sublimating the solids of the sublimable substance on the surface of the substrate by the sublimating unit while maintaining the solids of the sublimable substance in the pre-crystal transition state.
